(19) United States
(12) Patent Application Publication
(10) Pub. No.: US 2025/0079119 A1
(43) Pub. Date: Mar. 6, 2025

(54) METHOD FOR DETERMINING LINE SEGMENT INTERSECTIONS IN FIGURE OF WRITING DATA, APPARATUS FOR DETERMINING LINE SEGMENT INTERSECTIONS IN FIGURE OF WRITING DATA, STORAGE MEDIUM, AND ELECTRON BEAM LITHOGRAPHY APPARATUS

(71) Applicant: NuFlare Technology, Inc., Yokohama-shi (JP)

(72) Inventor: Shinji SAKAMOTO, Miyagi-gun (JP)

(73) Assignee: NuFlare Technology, Inc., Yokohama-shi (JP)

(21) Appl. No.: 18/733,003

(22) Filed: Jun. 4, 2024

(30) Foreign Application Priority Data
Jun. 19, 2023 (JP) 2023-100196

(51) Int. Cl. H01J 37/302; H01J 37/317

(52) U.S. Cl. CPC H01J 37/3023; H01J 37/3174

(57) ABSTRACT

According to one aspect of the present invention, a method for determining line segment intersections in a figure of writing data, includes: storing writing data in a storage device; reading the writing data from the storage device and determining a shape of a figure for each of figures with one of two directions perpendicular to each other as an x direction and the other as a y direction; and performing different intersection determination processing according to the shape of the figure and outputting a result, wherein in a case that the shape of the figure is an xy-monotone polygon and a convex polygon as a result of the shape determination, the intersection determination processing is omitted.

### CROSS-REFERENCE TO RELATED APPLICATION

This application is based upon and claims the benefit of priority from prior Japanese Patent Application No. 2023-100196 filed on Jun. 19, 2023 in Japan, the entire contents of which are incorporated herein by reference.

### BACKGROUND OF THE INVENTION

### Field of the Invention

One aspect of the present invention relates to a method for determining line segment intersections in a figure of writing data, an apparatus for determining line segment intersections in a figure of writing data, a program, and an electron beam lithography apparatus. For example, one aspect of the present invention relates to a method for determining the presence or absence of line segment intersections in a figure defined in writing data used for multiple beams writing.

### Related Art

Lithography technology, which is responsible for the progress of miniaturization of semiconductor devices, is an extremely important process that is the only pattern generation process among the semiconductor manufacturing processes. In recent years, as LSIs have become more highly integrated, the circuit line width required for semiconductor devices has become smaller year by year. Here, electron beam lithography technology is basically excellent in terms of resolution, and writing is performed on wafers and the like using an electron beam.

For example, there is a writing apparatus using multiple beams. Compared to the case of writing using a single electron beam, using multiple beams allows irradiation using a large amount of beams at a time, resulting in a significant improvement in throughput. In such a writing apparatus based on the multiple beams method, for example, an electron beam emitted from an electron emission source passes through a mask having a plurality of holes to form multiple beams, and each of the multiple beams is subjected to blanking control so that each beam that is not blocked is demagnified by an optical system, deflected by a deflector, and emitted to a desired position on a target object.

In single beam lithography represented by a variable-shaped (VSB) method, a desired pattern is written by combining the figures of trapezoids, rectangles, and triangles, for example. Therefore, when inspecting the shape of each figure defined in writing data input to the writing apparatus, it is sufficient to check the width, height, and the like of each figure. On the other hand, in multiple beams writing, writing is performed using a raster method. Therefore, in addition to the above-described figures, polygons having more vertices than a quadrangle can be included in the figure data. When creating such polygon data, there is a problem in that line segments forming a figure intersect with each other due to errors in vertex coordinates and the like. Therefore, before writing processing, it is necessary to check the presence or absence of intersection between line segments in a figure.

In such intersection determination processing, there is a problem in that the time required for the intersection determination increases as the number of line segments as intersection determination targets increases. Therefore, it is desired to shorten the time required for such intersection determination.

Here, although this is not for a polygon, a method for detecting self-intersection in a three-dimensional curve model is disclosed (see JP-A-2011-065534).

### BRIEF SUMMARY OF THE INVENTION

According to one aspect of the present invention, a method for determining line segment intersections in a figure of writing data, includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein in a case that the shape of the figure is an xy-monotone polygon and a convex polygon as a result of the shape determination, the intersection determination processing is omitted.

According to another aspect of the present invention, a method for determining line segment intersections in a figure of writing data, includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is an x-monotone polygon as a result of the shape determination, a line segment having an end point with a position increasing in the x direction so that the line segment extends monotonically in the x direction or having an end point with a position decreasing in the x direction so that the line segment extends monotonically in the −x direction is set as a reference line, presence or absence of intersection between line segments is determined with an opposite side including an x coordinate of the reference line in a line segment as an intersection determination target, and remaining line segments are excluded from intersection determination targets with respect to the reference line.

According to yet another aspect of the present invention, a method for determining line segment intersections in a figure of writing data, includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a y-monotone polygon as a result of the shape determination, a line segment having an end point with a position increasing in the y direction so that the line segment extends monotonically in the y direction or having an end point with a position decreasing in the y direction so that the line segment extends monotonically in the −y direction is set as a reference line, presence or absence of intersection between line segments is determined with an opposite side including a y coordinate of the reference line in a line segment as an intersection determination target, and remaining line segments are excluded from intersection determination targets with respect to the reference line.

According to yet another aspect of the present invention, a method for determining line segment intersections in a figure of writing data, includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a polygon as neither an x-monotone polygon nor a y-monotone polygon as a result of the shape determination, a displacement direction of an x coordinate and a displacement direction of a y coordinate of a next vertex from a position of a previous vertex are calculated for each of a plurality of vertices forming the polygon, and presence or absence of intersection between line segments is determined by using one of the x direction and the y direction as a scanning direction, the number of vertices with displacement directions changing from a positive direction to a negative direction or from the negative direction to the positive direction in the one direction being smaller than that in the other direction.

According to yet another aspect of the present invention, an apparatus for determining line segment intersections in a figure of writing data, includes:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is an xy-monotone polygon and a convex polygon as a result of the shape determination, the intersection determination processing is omitted.

According to yet another aspect of the present invention, an apparatus for determining line segment intersections in a figure of writing data, includes:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is an x-monotone polygon as a result of the shape determination, the intersection determination processing circuit sets, as a reference line, a line segment having an end point with a position increasing in the x direction so that the line segment extends monotonically in the x direction or having an end point with a position decreasing in the x direction so that the line segment extends monotonically in the −x direction, determines presence or absence of intersection between line segments with an opposite side including an x coordinate of the reference line in a line segment as an intersection determination target, and excludes remaining line segments from intersection determination targets with respect to the reference line.

According to yet another aspect of the present invention, an apparatus for determining line segment intersections in a figure of writing data, includes:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is a y-monotone polygon as a result of the shape determination, the intersection determination processing circuit sets, as a reference line, a line segment having an end point with a position increasing in the y direction so that the line segment extends monotonically in the y direction or having an end point with a position decreasing in the y direction so that the line segment extends monotonically in the −y direction, determines presence or absence of intersection between line segments with an opposite side including a y coordinate of the reference line in a line segment as an intersection determination target, and excludes remaining line segments from intersection determination targets with respect to the reference line.

According to yet another aspect of the present invention, an apparatus for determining line segment intersections in a figure of writing data, includes:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is a polygon as neither an x-monotone polygon nor a y-monotone polygon as a result of the shape determination, the intersection determination processing circuit calculates a displacement direction of an x coordinate and a displacement direction of a y coordinate of a next vertex from a position of a previous vertex for each of a plurality of vertices forming the polygon, and determines presence or absence of intersection between line segments by using one of the x direction and the y direction as a scanning direction, the number of vertices with displacement directions changing from a positive direction to a negative direction or from the negative direction to the positive direction in the one direction being smaller than that in the other direction.

According to yet another aspect of the present invention, a non-transitory computer-readable storage medium storing a program for causing a computer to execute processing includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein in a case that the shape of the figure is an xy-monotone polygon and a convex polygon as a result of the shape determination, the intersection determination processing is omitted.

According to yet another aspect of the present invention, a non-transitory computer-readable storage medium storing a program for causing a computer to execute processing includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is an x-monotone polygon as a result of the shape determination, a line segment having an end point with a position increasing in the x direction so that the line segment extends monotonically in the x direction or having an end point with a position decreasing in the x direction so that the line segment extends monotonically in the −x direction is set as a reference line, presence or absence of intersection between line segments is determined with an opposite side including an x coordinate of the reference line in a line segment as an intersection determination target, and remaining line segments are excluded from intersection determination targets with respect to the reference line.

According to yet another aspect of the present invention, a non-transitory computer-readable storage medium storing a program for causing a computer to execute processing includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a y-monotone polygon as a result of the shape determination, a line segment having an end point with a position increasing in the y direction so that the line segment extends monotonically in the y direction or having an end point with a position decreasing in the y direction so that the line segment extends monotonically in the −y direction is set as a reference line, presence or absence of intersection between line segments is determined with an opposite side including a y coordinate of the reference line in a line segment as an intersection determination target, and remaining line segments are excluded from intersection determination targets with respect to the reference line.

According to yet another aspect of the present invention, a non-transitory computer-readable storage medium storing a program for causing a computer to execute processing includes:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a polygon as neither an x-monotone polygon nor a y-monotone polygon as a result of the shape determination, a displacement direction of an x coordinate and a displacement direction of a y coordinate of a next vertex from a position of a previous vertex are calculated for each of a plurality of vertices forming the polygon, and presence or absence of intersection between line segments is determined by using one of the x direction and the y direction as a scanning direction, the number of vertices with displacement directions changing from a positive direction to a negative direction or from the negative direction to the positive direction in the one direction being smaller than that in the other direction.

According to yet another aspect of the present invention, an electron beam lithography apparatus, includes:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is an xy-monotone polygon and a convex polygon as a result of the shape determination, the intersection determination processing is omitted.

According to yet another aspect of the present invention, an electron beam lithography apparatus, includes:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is an x-monotone polygon as a result of the shape determination, the intersection determination processing circuit sets, as a reference line, a line segment having an end point with a position increasing in the x direction so that the line segment extends monotonically in the x direction or having an end point with a position decreasing in the x direction so that the line segment extends monotonically in the −x direction, determines presence or absence of intersection between line segments with an opposite side including an x coordinate of the reference line in a line segment as an intersection determination target, and excludes remaining line segments from intersection determination targets with respect to the reference line.

According to yet another aspect of the present invention, an electron beam lithography apparatus, includes:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is a y-monotone polygon as a result of the shape determination, the intersection determination processing circuit sets, as a reference line, a line segment having an end point with a position increasing in the y direction so that the line segment extends monotonically in the y direction or having an end point with a position decreasing in the y direction so that the line segment extends monotonically in the −y direction, determines presence or absence of intersection between line segments with an opposite side including a y coordinate of the reference line in a line segment as an intersection determination target, and excludes remaining line segments from intersection determination targets with respect to the reference line.

According to yet another aspect of the present invention, an electron beam lithography apparatus, includes:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is a polygon as neither an x-monotone polygon nor a y-monotone polygon as a result of the shape determination, the intersection determination processing circuit calculates a displacement direction of an x coordinate and a displacement direction of a y coordinate of a next vertex from a position of a previous vertex for each of a plurality of vertices forming the polygon, and determines presence or absence of intersection between line segments by using one of the x direction and the y direction as a scanning direction, the number of vertices with displacement directions changing from a positive direction to a negative direction or from the negative direction to the positive direction in the one direction being smaller than that in the other direction.

### BRIEF DESCRIPTION OF THE DRAWINGS

FIG. 1 is a conceptual diagram showing the configuration of a writing apparatus according to a first embodiment;

FIG. 2 is a conceptual diagram showing the configuration of a shaping aperture array substrate in the first embodiment;

FIG. 3 is a cross-sectional view showing the configuration of a blanking aperture array mechanism in the first embodiment;

FIG. 4 is a diagram showing an example of a polygon without line segment intersections in the first embodiment;

FIG. 5 is a diagram showing an example of a polygon with line segment intersections in the first embodiment;

FIG. 6 is a diagram for explaining an example of a method of determining the intersection of line segments in a first comparative example of the first embodiment;

FIG. 7 is a diagram showing an example of a line segment in a plane scanning method in the first embodiment;

FIG. 8 is a diagram showing another example of a line segment in the plane scanning method in the first embodiment;

FIG. 9 is a flowchart showing an example of main steps of a method for determining line segment intersections in a figure of writing data according to the first embodiment;

FIG. 10 is a block diagram showing an example of the internal configuration of a shape determination processing unit in the first embodiment;

FIG. 11 is a diagram showing an example of an x-monotone polygon in the first embodiment;

FIG. 12 is a diagram showing an example of a y-monotone polygon in the first embodiment;

FIG. 13 is a diagram showing an example of an xy-monotone polygon in the first embodiment;

FIG. 14 is a diagram showing an example of a convex polygon in the first embodiment;

FIG. 15 is a diagram showing another example of a convex polygon in the first embodiment;

FIG. 16 is a flowchart showing an example of internal steps of an x-monotone polygon intersection determination processing step in the first embodiment;

FIG. 17 is a block diagram showing an example of the internal configuration of an intersection determination processing unit in the first embodiment;

FIG. 18 is a diagram for explaining the plane scanning method using an x-monotone polygon in the first embodiment;

FIG. 19 is a diagram showing an example of circumscribed rectangles of two line segments that are intersection determination targets in the first embodiment;

FIG. 20 is a diagram showing another example of circumscribed rectangles of two line segments that are intersection determination targets in the first embodiment;

FIG. 21 is a diagram showing an example of the positional relationship between line segments as intersection determination targets in the first embodiment;

FIG. 22 is a diagram for explaining a method of determining a cross product in the first embodiment;

FIG. 23 is a diagram for explaining the plane scanning method using an x-monotone polygon in the first embodiment;

FIG. 24 is a flowchart showing an example of internal steps of a non-monotone polygon intersection determination processing step in the first embodiment;

FIG. 25 is a diagram showing an example of a non-monotone polygon in the first embodiment;

FIG. 26 is a table showing an example of the displacement direction of the x coordinate and the displacement direction of the y coordinate in the first embodiment;

FIG. 27 is a diagram showing an example of the number of intersection determinations in the x direction and the y direction in the first embodiment;

FIG. 28 is a diagram showing an example of a y-monotone polygon in a modification example of the first embodiment;

FIG. 29 is a diagram showing an example of an x-monotone polygon in a modification example of the first embodiment;

FIG. 30 is a diagram showing an example of an xy-monotone polygon in a modification example of the first embodiment;

FIG. 31 is a conceptual diagram for explaining an example of a writing operation in the first embodiment;

FIG. 32 is a diagram showing an example of a multiple beams irradiation region and writing target pixels in the first embodiment; and

FIG. 33 is a diagram for explaining an example of a multiple beams writing operation in the first embodiment.

### DETAILED DESCRIPTION OF THE INVENTION

Hereinafter, a method capable of efficiently determining the intersection of line segments in a figure of polygonal figure data defined in writing (or “drawing”) data will be provided by way of embodiments.

In addition, in the following embodiments, a configuration using an electron beam as an example of a charged particle beam will be described. However, the charged particle beam is not limited to an electron beam, and may be a beam using a charged particle such as an ion beam.

### First Embodiment

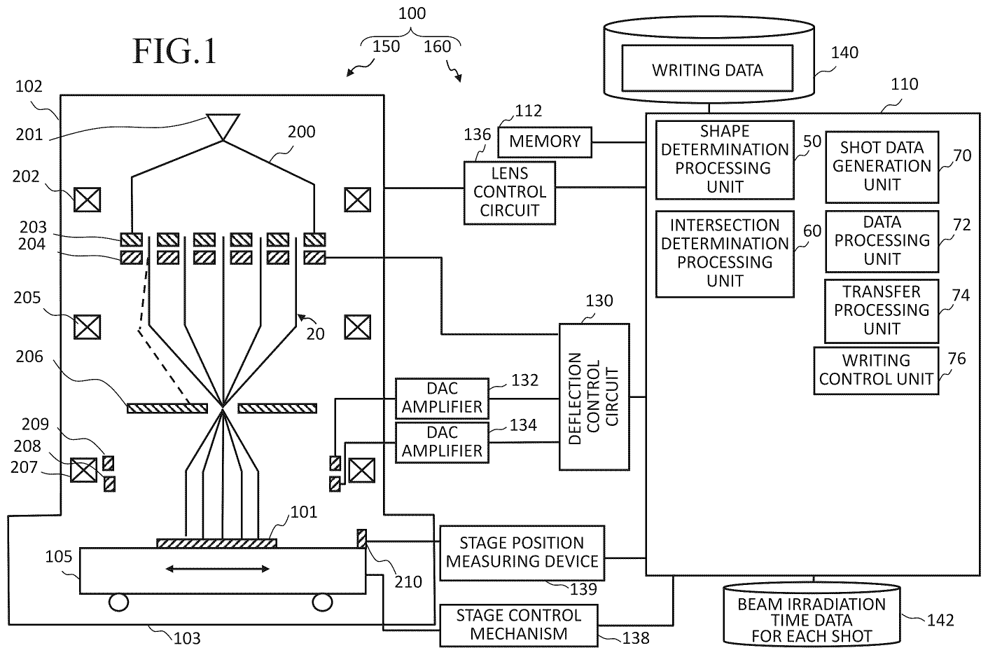

FIG. 1 is a conceptual diagram showing the configuration of a writing apparatus according to a first embodiment. In FIG. 1, a writing apparatus 100 includes a writing mechanism 150 and a control system circuit 160. The writing apparatus 100 is an example of a multi-charged particle beam lithography apparatus and an example of a multi-charged particle beam exposure apparatus. The writing mechanism 150 includes an electron optical column 102 (electron beam column) and a writing chamber 103. An electron emission source 201, an illumination lens 202, a shaping aperture array substrate 203, a blanking aperture array mechanism 204, a demagnifying lens 205, a limiting aperture substrate 206, an objective lens 207, a deflector 208, and a deflector 209 are arranged inside the electron optical column 102.

An XY stage 105 is arranged inside the writing chamber 103. On the XY stage 105, a target object 101 such as a mask, which becomes a writing target substrate during writing (during exposure), is arranged. The target object 101 includes an exposure mask used in manufacturing a semiconductor device, a semiconductor substrate (silicon wafer) on which a semiconductor device is manufactured, and the like. In addition, the target object 101 includes mask blanks which are coated with resist and on which nothing has been written yet.

In addition, a mirror 210 for measuring the position of the XY stage 105 is further arranged on the XY stage 105.

The control system circuit 160 includes a control calculator 110, a memory 112, a deflection control circuit 130, digital-to-analog conversion (DAC) amplifiers 132 and 134, a lens control circuit 136, a stage control mechanism 138, a stage position measuring device 139, and storage devices 140 and 142 such as a magnetic disk drive. The control calculator 110, the memory 112, the deflection control circuit 130, the lens control circuit 136, the stage control mechanism 138, the stage position measuring device 139, and the storage devices 140 and 142 are connected to each other through a bus (not shown). The DAC amplifiers 132 and 134 and the blanking aperture array mechanism 204 are connected to the deflection control circuit 130. The deflector 209 is formed by electrodes having four or more poles, and each electrode is controlled by the deflection control circuit 130 through the DAC amplifier 132. The deflector 208 is formed by electrodes having four or more poles, and each electrode is controlled by the deflection control circuit 130 through the DAC amplifier 134. For example, a group of electromagnetic lenses such as the illumination lens 202, the demagnifying lens 205, and the objective lens 207 are controlled by the lens control circuit 136.

The position of the XY stage 105 is controlled by driving motors for each axis (not shown) controlled by the stage control mechanism 138. The stage position measuring device 139 measures the position of the XY stage 105 using the principle of laser interferometry by receiving the reflected light from the mirror 210.

A shape determination processing unit 50, an intersection determination processing unit 60, a shot data generation unit 70, a data processing unit 72, a transfer processing unit 74, and a writing control unit 76 are arranged in the control calculator 110. Each “˜ unit”, such as the shape determination processing unit 50, the intersection determination processing unit 60, the shot data generation unit 70, the data processing unit 72, the transfer processing unit 74, and the writing control unit 76, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input and output to and from the shape determination processing unit 50, the intersection determination processing unit 60, the shot data generation unit 70, the data processing unit 72, the transfer processing unit 74, and the writing control unit 76 and information being calculated are stored in the memory 112 each time.

The writing operation of the writing apparatus 100 is controlled by the writing control unit 76. In addition, processing for the transfer of beam irradiation time data of each shot to the deflection control circuit 130 is controlled by the transfer processing unit 74.

In addition, writing data (chip data) is input from outside the writing apparatus 100 and is stored in the storage device 140. The chip data defines information on a plurality of figures forming a chip pattern. Specifically, for each figure, for example, a coordinate string of each vertex coordinate is defined. In addition, it is also preferable to define a figure code.

Here, FIG. 1 describes components necessary for explaining the first embodiment. The writing apparatus 100 may usually include other necessary components.

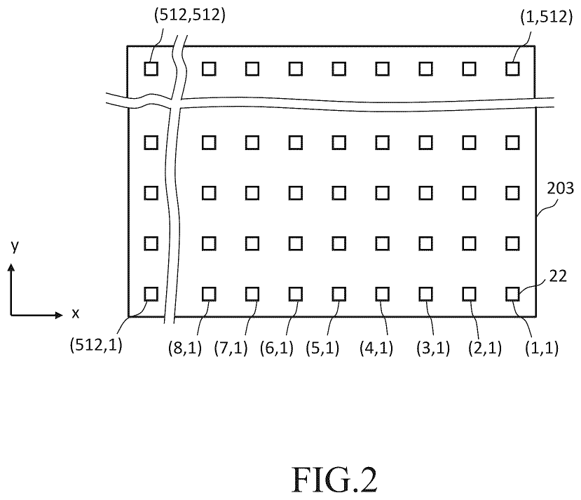

FIG. 2 is a conceptual diagram showing the configuration of a shaping aperture array substrate in the first embodiment. In FIG. 2, in the shaping aperture array substrate 203, holes (openings) 22 are formed in a matrix of p rows long (in the y direction) and q columns wide (in the x direction) (p, q≥2) at a predetermined arrangement pitch. The example in FIG. 2 shows a case where, for example, 512×512 rows of holes 22 are formed in length and width directions (x and y directions). The number of holes 22 is not limited to this. For example, 32×32 rows of holes 22 may be formed. The holes 22 are formed in rectangles having the same dimension and shape together. Alternatively, the holes 22 may be circles having the same diameter. Some of electron beams 200 pass through each of the plurality of holes 22 to form multiple beams 20. In other words, the shaping aperture array substrate 203 forms and emits the multiple beams 20. The shaping aperture array substrate 203 is an example of an emission source for the multiple beams 20.

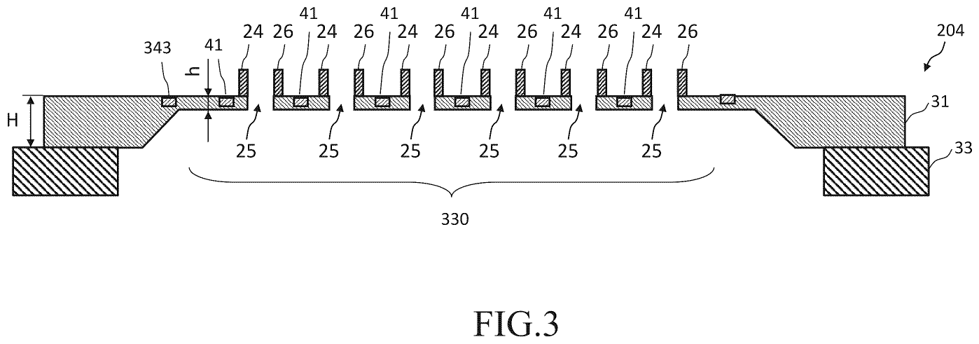

FIG. 3 is a cross-sectional view showing the configuration of the blanking aperture array mechanism in the first embodiment. In the blanking aperture array mechanism 204, as shown in FIG. 3, a blanking aperture array substrate 31 using a semiconductor substrate formed of silicon or the like is arranged on a support base 33. In a membrane region 330 at the center of the blanking aperture array substrate 31, a passage hole 25 (opening) through which each of the multiple beams 20 passes is opened at a position corresponding to each hole 22 of the shaping aperture array substrate 203 shown in FIG. 2. Then, a set of a control electrode 24 and a counter electrode 26 (blanker: blanking deflector) are arranged at positions facing each other with a corresponding passage hole 25 among the plurality of passage holes 25 interposed therebetween. In addition, a control circuit 41 (logic circuit) to apply a deflection voltage to the control electrode 24 for each passage hole 25 is arranged inside the blanking aperture array substrate 31 near each passage hole 25. The counter electrode 26 for each beam is grounded.

In the control circuit 41, an amplifier (an example of a switching circuit), which is not shown, is arranged. As an example of the amplifier, a CMOS (Complementary MOS) inverter circuit serving as a switching circuit is arranged. Either an L (low) potential (for example, a ground potential) lower than a threshold voltage or an H (high) potential (for example, 1.5 V) equal to or greater than the threshold voltage is applied as a control signal to the input (IN) of the CMOS inverter circuit. In the first embodiment, in a state in which the L potential is applied to the input (IN) of the CMOS inverter circuit, the output (OUT) of the CMOS inverter circuit applied to the control circuit 41 has a positive potential (Vdd), and the corresponding beam is deflected by the electric field due to the potential difference from the ground potential of the counter electrode 26 and shielded by the limiting aperture substrate 206. In this manner, beam OFF control is made. On the other hand, in a state in which the H potential is applied to the input (IN) of the CMOS inverter circuit (active state), the output (OUT) of the CMOS inverter circuit has a ground potential, and there is no potential difference from the ground potential of the counter electrode 26. Therefore, since the corresponding beam is not deflected, the beam passes through the limiting aperture substrate 206. In this manner, beam ON control is made. Blanking control is made by such deflection.

Next, a specific example of the operation of the writing mechanism 150 will be described. An electron beam 200 emitted from the electron emission source 201 (emission source) illuminates the entire shaping aperture array substrate 203 almost vertically through the illumination lens 202. A plurality of rectangular holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form, for example, rectangular multiple beams (a plurality of electron beams) 20. Such multiple beams 20 pass through corresponding blankers of the blanking aperture array mechanism 204. Each of the blankers performs blanking control on each beam passing therethrough so that the beam is in an ON state during the set writing time (beam irradiation time).

The multiple beams 20 that have passed through the blanking aperture array mechanism 204 are reduced by the demagnifying lens 205 and travel toward a central hole formed in the limiting aperture substrate 206. Here, the electron beam deflected by the blanker of the blanking aperture array mechanism 204 is displaced from the central hole of the limiting aperture substrate 206 and is blocked by the limiting aperture substrate 206. On the other hand, the electron beam that is not deflected by the blanker of the blanking aperture array mechanism 204 passes through the central hole of the limiting aperture substrate 206 as shown in FIG. 1. Thus, the limiting aperture substrate 206 blocks each beam that is deflected by the blanker of the blanking aperture array mechanism 204 so as to be in a beam OFF state. Then, by the beam that has passed through the limiting aperture substrate 206 and is formed from the beam ON state to the beam OFF state, each beam of one shot is formed. The multiple beams 20 that have passed through the limiting aperture substrate 206 are focused by the objective lens 207 to become a pattern image having a desired reduction ratio, and all of the multiple beams 20 that have passed through the limiting aperture substrate 206 are collectively deflected in the same direction by the deflector 208 and the deflector 209 and emitted to each irradiation position on the target object 101 of each beam. In addition, for example, when the XY stage 105 is continuously moving, tracking control is performed by the deflector 208 so that the irradiation position of the beam follows the movement of the XY stage 105. The multiple beams 20 emitted at one time are ideally arranged at a pitch obtained by multiplying the arrangement pitch of the plurality of holes 22 of the shaping aperture array substrate 203 by the desired reduction ratio described above.

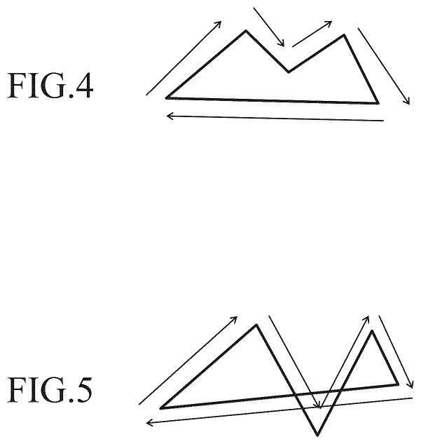

FIG. 4 is a diagram showing an example of a polygon without line segment intersections in the first embodiment.

FIG. 5 is a diagram showing an example of a polygon with line segment intersections in the first embodiment.

As described above, in multiple beams writing, since writing is performed using a raster method, polygons having more vertices than a quadrangle, such as a rectangle or a trapezoid, can be included in the figure data. In general, a polygonal figure is expressed by a series of consecutive vertices. For each piece of figure data of writing data, for example, the coordinates of each vertex are defined so as to rotate clockwise around the figure with the vertex at the lower left position of the figure as a reference. Then, it is defined that a figure is present on the right side of a line segment connecting two vertices as a pair from the start point to the end point. When creating such polygon data, as shown in FIG. 5, there is a problem in that line segments forming a figure intersect with each other due to errors in vertex coordinates and the like. Therefore, before writing processing, it is necessary to check the presence or absence of intersection between line segments in a figure.

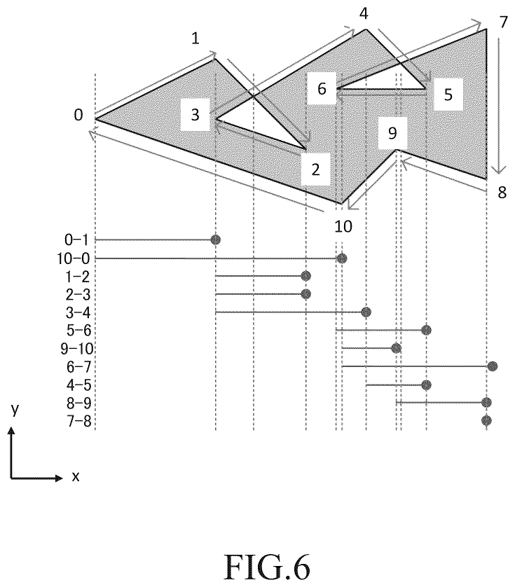

FIG. 6 is a diagram for explaining an example of a method for determining the intersection of line segments in a first comparative example of the first embodiment. In the comparative example shown in FIG. 6, numbers of 0 to 10 are set at the vertices of a polygon. The comparative example in FIG. 6 shows a plane scanning method. In the example shown in FIG. 6, line segment information is replaced in parallel to the x-axis. Then, one line segment is set as a reference line, and intersection determination is performed for a line segment that is likely to intersect with the reference line. In the example shown in FIG. 6, assuming that the line segment 0-1 is a reference line, the line segment 0-1 may intersect with the line segment 10-0. Therefore, intersection determination for the line segment 0-1 and the line segment 10-0 is performed. Then, assuming that the line segment 10-0 is a reference line, the line segment 10-0 may intersect with the line segments 1-2, 2-3, and 3-4. Therefore, intersection determination is performed between the line segment 10-0 and the line segments 1-2, 2-3, and 3-4 in this order. This operation is repeated. However, in such intersection determination processing, there is a problem in that the time required for the intersection determination increases as the number of line segments as intersection determination targets increases. Therefore, it is desired to shorten the time required for such intersection determination.

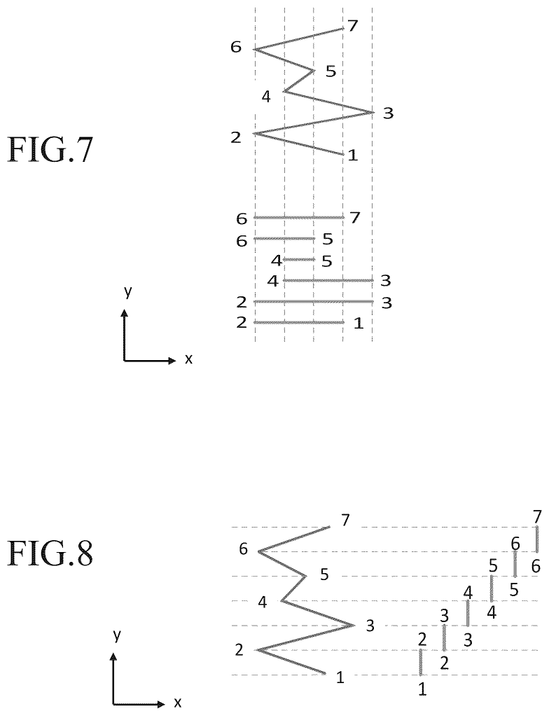

FIG. 7 is a diagram showing an example of line segments in the plane scanning method in the first embodiment. In the example shown in FIG. 7, for example, six line segments connecting vertices 1 to 7 in order are shown. The example in FIG. 7 shows a case where the displacement direction of the vertex in the x direction is reversed for each line segment. These six line segments are replaced in parallel to the x-axis. In other words, the six line segments are transformed so as to be projected onto the x-axis. In this case, as shown in FIG. 7, assuming that the line segment 1-2 is a reference line, the line segment 1-2 may intersect all of the line segments 2-3, 3-4, 4-5, 5-6, and 6-7. Therefore, the intersection determination is required five times. Therefore, the intersection determination processing requires a long time.

FIG. 8 is a diagram showing another example of line segments in the plane scanning method in the first embodiment. In the example shown in FIG. 8, six line segments connecting vertices 1 to 7 in order are shown, as in FIG. 7. In the example shown in FIG. 8, in the y direction, there are a plurality of line segments that monotonically extend. Therefore, in FIG. 8, these six line segments are replaced in parallel to the y-axis. In other words, the line segments are transformed so as to be projected onto the y-axis. In this case, as shown in FIG. 8, assuming that the line segment 1-2 is a reference line, it can be seen that there is no line segment that may intersect the line segment 1-2. Therefore, the intersection determination processing can be completed in a short time.

As shown in FIGS. 7 and 8, when performing the intersection determination processing using the plane scanning method, it is possible to increase the processing speed (reduce the processing time) by reducing the number of line segments that may intersect with the reference line. Therefore, in the first embodiment, the number of intersection determinations is reduced for each target figure.

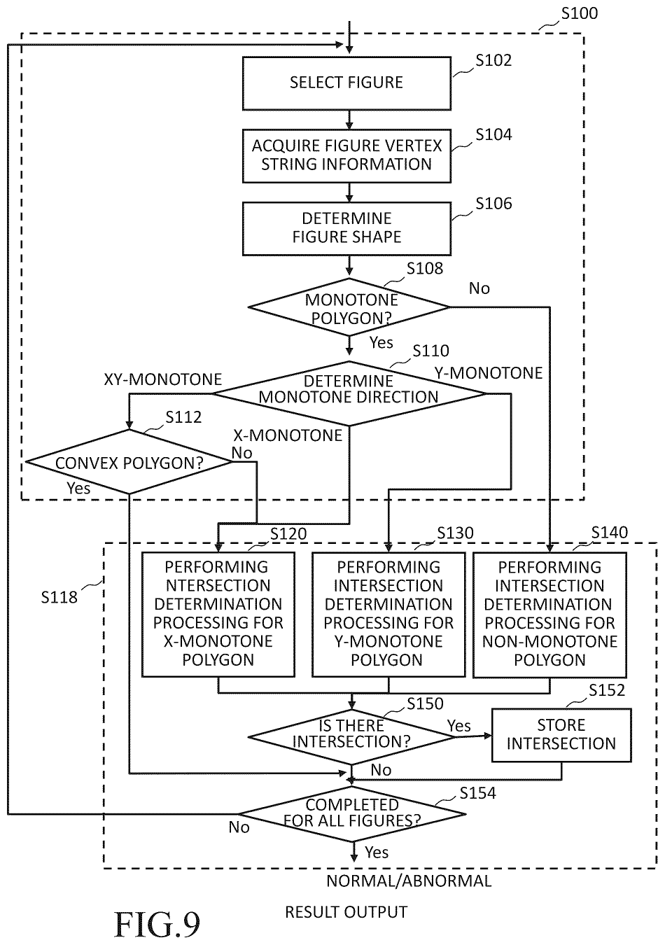

FIG. 9 is a flowchart showing an example of main steps of a method for determining line segment intersections in a figure of writing data according to the first embodiment. In FIG. 9, the method for determining line segment intersections in a figure of writing data according to the first embodiment includes a figure shape determination processing step (S100) and an intersection determination processing step (S118).

In the figure shape determination processing step (S100), a series of steps including a figure selection step (S102), a figure vertex string information acquisition step (S104), a figure shape determination processing step (S106), a determination step (S108), a determination step (S110), and a determination step (S112) are performed as internal steps.

In the intersection determination processing step (S118), a series of steps including an x-monotone polygon intersection determination processing step (S120), a y-monotone polygon intersection determination processing step (S130), a non-monotone polygon intersection determination processing step (S140), a determination step (S150), an intersection storage step (S152), and a determination step (S154) are performed as internal steps.

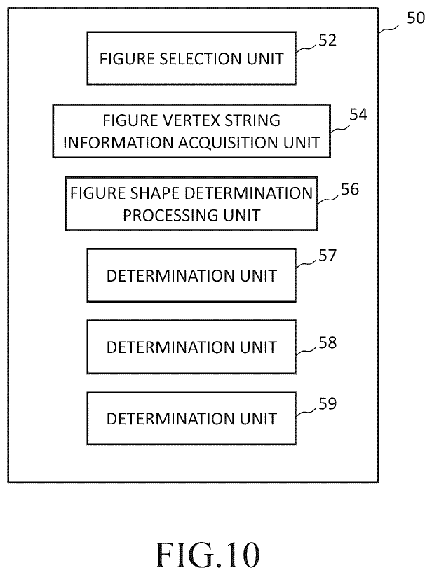

FIG. 10 is a block diagram showing an example of the internal configuration of a shape determination processing unit in the first embodiment. In FIG. 10, a figure selection unit 52, a figure vertex string information acquisition unit 54, a figure shape determination processing unit 56, a determination unit 57, a determination unit 58, and a determination unit 59 are arranged in the shape determination processing unit 50. Each “˜ unit”, such as the figure selection unit 52, the figure vertex string information acquisition unit 54, the figure shape determination processing unit 56, the determination unit 57, the determination unit 58, and the determination unit 59, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input and output to and from the figure selection unit 52, the figure vertex string information acquisition unit 54, the figure shape determination processing unit 56, the determination unit 57, the determination unit 58, and the determination unit 59 and information being calculated are stored in the memory 112 each time.

As the figure shape determination processing step (S100), the shape determination processing unit 50 reads writing data from the storage device 140, and determines a shape of a figure for each of figures with one of two directions perpendicular to each other as the x direction and the other as the y direction. Specifically, the shape determination processing unit 50 operates as follows.

As the figure selection step (S102), the figure selection unit 52 reads the writing data from the storage device 140 and selects the defined figure data one by one. For example, it is preferable to read the writing data for each stripe region, which will be described later.

As the figure vertex string information acquisition step (S104), the figure vertex string information acquisition unit 54 acquires figure vertex string information for each figure. The figure vertex string information includes, for example, a plurality of vertex coordinates arranged so as to rotate clockwise around the figure from the reference vertex. For example, in the case of an n-gon (n is a natural number), information on a string of n vertex coordinates is acquired. Specifically, for example, string information (vertex string information) of a plurality of vertex coordinates arranged so as to rotate clockwise around the figure from the reference vertex, which is defined as figure data, is acquired from the writing data.

As the figure shape determination processing step (S106), the figure shape determination processing unit 56 determines the shape of each figure. Here, for example, it is determined that each figure is an x-monotone polygon, a y-monotone polygon, an xy-monotone polygon, or a non-monotone polygon. In addition, if the figure is an xy-monotone polygon, it is further determined whether or not the figure is a convex polygon.

FIG. 11 is a diagram showing an example of an x-monotone polygon in the first embodiment.

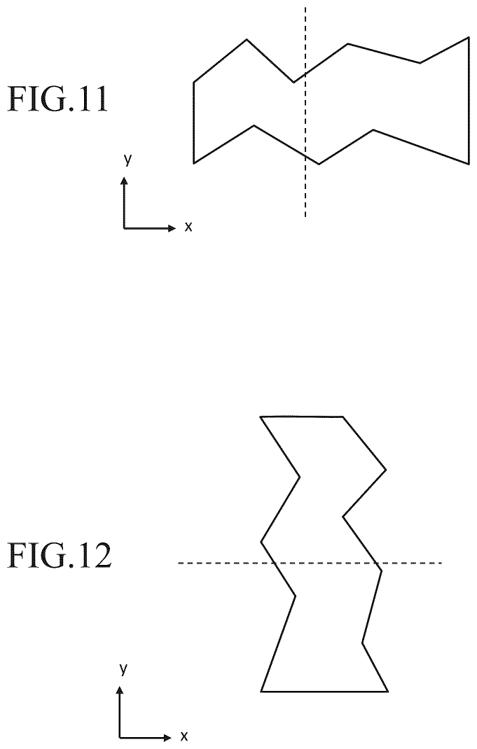

FIG. 12 is a diagram showing an example of a y-monotone polygon in the first embodiment.

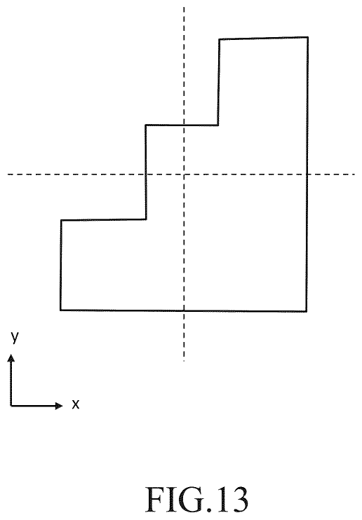

FIG. 13 is a diagram showing an example of an xy-monotone polygon in the first embodiment.

A monotone polygon is defined as a polygon in which the number of intersections between the polygon and one of the straight lines in two directions (x and y directions) perpendicular to each other is two or less at any position. Examples of the monotone polygon include an x-monotone polygon, an y-monotone polygon, and an xy-monotone polygon. A polygon that is not a monotone polygon is a non-monotone polygon.

As shown in FIG. 11, the x-monotone polygon is, for example, a figure formed by a plurality of line segments that extend sequentially in the x direction and then returns sequentially in the −x direction. In addition, as shown in FIG. 11, the x-monotone polygon has a characteristic that the number of intersections between the polygon and the straight line in the y direction is two or less at any position in the x direction. In addition, it is assumed that no intersection is counted for a line segment that completely overlaps the straight line in the y direction.

As shown in FIG. 12, the y-monotone polygon is, for example, a figure formed by a plurality of line segments that extend sequentially in the y direction and then returns sequentially in the −y direction. In addition, as shown in FIG. 12, the y-monotone polygon has a characteristic that the number of intersections between the polygon and the straight line in the x direction is two or less at any position in the y direction. In addition, it is assumed that no intersection is counted for a line segment that completely overlaps the straight line in the x direction.

The xy-monotone polygon has characteristics of both the x-monotone polygon and the y-monotone polygon. As shown in FIG. 13, the xy-monotone polygon is, for example, a figure formed by a plurality of line segments that extend sequentially in the x direction and then returns sequentially in the −x direction and is, for example, a figure formed by a plurality of line segments that extend sequentially in the y direction and then returns sequentially in the −y direction. Therefore, as shown in FIG. 13, the xy-monotone polygon has a characteristic that the number of intersections between the polygon and the straight line in the y direction is two or less at any position in the x direction. In addition, it is assumed that no intersection is counted for a line segment that completely overlaps the straight line in the y direction. Similarly, as shown in FIG. 13, the xy-monotone polygon has a characteristic that the number of intersections between the polygon and the straight line in the x direction is two or less at any position in the y direction. In addition, it is assumed that no intersection is counted for a line segment that completely overlaps the straight line in the x direction.

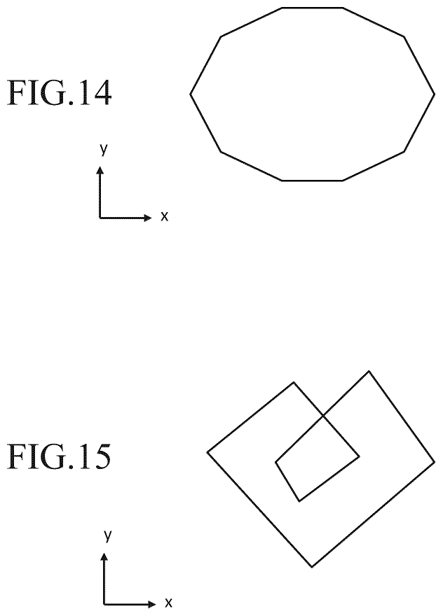

FIG. 14 is a diagram showing an example of a convex polygon in the first embodiment. The convex polygon is a polygon in which all interior angles are less than 180°. If the convex polygon is an xy-monotone polygon, the line segments do not intersect with each other, as shown in FIG. 14.

FIG. 15 is a diagram showing another example of a convex polygon in the first embodiment. FIG. 15 shows an example of a convex polygon that is not an xy-monotone polygon. If the convex polygon is not an xy-monotone polygon, some of the line segments intersect with each other, as shown in FIG. 15.

As the determination step (S108), the determination unit 57 determines whether or not the target figure whose shape has been determined is a monotone polygon. When the figure whose shape has been determined is a monotone polygon, the process proceeds to the determination step (S110). When the figure whose shape has been determined is not a monotone polygon, the process proceeds to the non-monotone polygon intersection determination processing step (S140).

As the determination step (S110), the determination unit 58 determines which monotone polygon among an x-monotone polygon, a y-monotone polygon, and an xy-monotone polygon the target figure, which is a monotone polygon, is. When the target figure is an x-monotone polygon, the process proceeds to the x-monotone polygon intersection determination processing step (S120). When the target figure is a y-monotone polygon, the process proceeds to the y-monotone polygon intersection determination processing step (S130). When the target figure is an xy-monotone polygon, the process proceeds to the determination step (S112).

As the determination step (S112), the determination unit 59 determines whether or not the target figure, which is an xy-monotone polygon, is a convex polygon. When the target figure, which is an xy-monotone polygon, is not a convex polygon, the process proceeds to the x-monotone polygon intersection determination processing step (S120). Alternatively, the process may proceed to the y-monotone polygon intersection determination processing step (S130).

As described above, in the convex polygon that is an xy-monotone polygon, the line segments do not intersect with each other, as shown in FIG. 14. Therefore, when the shape of the figure is an xy-monotone polygon and a convex polygon as a result of shape determination, the processing for determining intersections in the figure is omitted on the assumption that there is no intersection between the line segments forming the figure. Then, the process proceeds to the determination step (S154).

As the intersection determination processing step (S118), the intersection determination processing unit 60 performs different intersection determination processing for each figure depending on the shape of the figure, and outputs the result. Specifically, the intersection determination processing unit 60 operates as follows.

As the x-monotone polygon intersection determination processing step (S120), the intersection determination processing unit 60 performs, for each target figure that is an x-monotone polygon, intersection determination processing according to the x-monotone polygon. The same intersection determination processing as for the x-monotone polygon is performed for the xy-monotone polygon that is not a convex polygon.

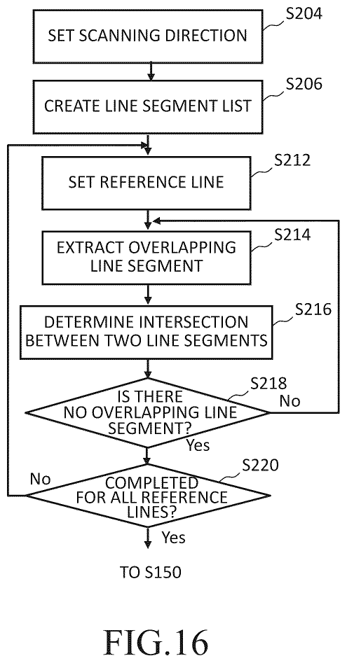

FIG. 16 is a flowchart showing an example of internal steps of the x-monotone polygon intersection determination processing step in the first embodiment. In FIG. 16, in the x-monotone polygon intersection determination processing step (S120), a series of steps including a scanning direction setting step (S204), a line segment list creation step (S206), a reference line setting step (S212), an overlapping line segment extraction step (S214), a two line segments intersection determination step (S216), a determination step (S218), and a determination step (S220) are performed as internal steps.

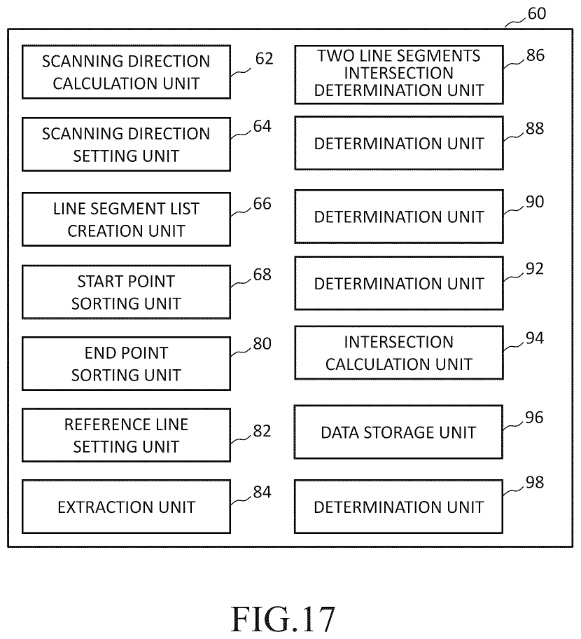

FIG. 17 is a block diagram showing an example of the internal configuration of an intersection determination processing unit in the first embodiment. In FIG. 17, a scanning direction calculation unit 62, a scanning direction setting unit 64, a line segment list creation unit 66, a start point sorting unit 68, an end point sorting unit 80, a reference line setting unit 82, an extraction unit 84, a two line segments intersection determination unit 86, a determination unit 88, a determination unit 90, a determination unit 92, an intersection calculation unit 94, a data storage unit 96, and a determination unit 98 are arranged in the intersection determination processing unit 60. Each “˜ unit”, such as the scanning direction calculation unit 62, the scanning direction setting unit 64, the line segment list creation unit 66, the start point sorting unit 68, the end point sorting unit 80, the reference line setting unit 82, the extraction unit 84, the two line segments intersection determination unit 86, the determination unit 88, the determination unit 90, the determination unit 92, the intersection calculation unit 94, the data storage unit 96, and the determination unit 98, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input and output to and from the scanning direction calculation unit 62, the scanning direction setting unit 64, the line segment list creation unit 66, the start point sorting unit 68, the end point sorting unit 80, the reference line setting unit 82, the extraction unit 84, the two line segments intersection determination unit 86, the determination unit 88, the determination unit 90, the determination unit 92, the intersection calculation unit 94, the data storage unit 96, and the determination unit 98 and information being calculated are stored in the memory 112 each time.

As the scanning direction setting step (S204) in FIG. 16, the scanning direction setting unit 64 sets a scanning direction in the plane scanning method for the x-monotone polygon to the x direction.

As the line segment list creation step (S206), the line segment list creation unit 66 replaces each line segment of the target figure, which is an x-monotone polygon, in parallel to the set scanning direction. Here, each line segment of the target figure is replaced in parallel to the x direction. In other words, each line segment of the target figure is transformed so as to be projected onto the x-direction axis. As a result, a list of line segments parallel to the x direction is created.

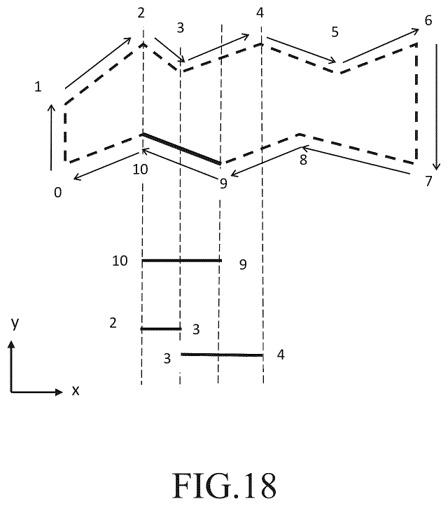

FIG. 18 is a diagram for explaining the plane scanning method using an x-monotone polygon in the first embodiment. In the example in FIG. 18, an example of an 11-sided x-monotone polygon having vertices 0 to 10 is shown. In the example shown in FIG. 18, nine line segments 1-2, 2-3, 3-4, 4-5, 5-6, 7-8, 8-9, 9-10, and 10-0 parallel to the x direction are defined in the list. The line segments 0-1 and 6-7 are points, and there are no line segments parallel to the x direction.

As described above, the x-monotone polygon is formed by a plurality of line segments in which each line segment between vertices extends sequentially in the +x direction and then returns sequentially in the −x direction. Alternatively, the x-monotone polygon is formed by a plurality of line segments that extend sequentially in the −x direction and then returns sequentially in the +x direction. The example in FIG. 18 shows a case where the line segment is formed by a plurality of line segments that extend sequentially in the +x direction and then return sequentially in the −x direction.

Therefore, line segments that monotonically extend sequentially in the +x direction do not intersect with each other. Similarly, line segments that monotonically extend sequentially in the −x direction do not intersect with each other. Therefore, line segments that may intersect with each of the line segments extending sequentially in the +x direction are only line segments whose x coordinates overlap each of the line segments extending sequentially in the +x direction among the line segments extending sequentially in the −x direction. Similarly, line segments that may intersect with each of the line segments extending sequentially in the −x direction are only line segments whose x coordinates overlap each of the line segments extending sequentially in the −x direction among the line segments extending sequentially in the +x direction. Therefore, it is sufficient to perform intersection determination by using only each line segment extending in one direction, among the line segments extending sequentially in the +x direction and the line segments extending sequentially in the −x direction, as a reference line.

Therefore, when the shape of the figure is an x-monotone polygon as a result of the shape determination, the intersection determination processing unit 60 sets, as a reference line, a line segment whose end point position increases in the x direction so that the line segment extends monotonically in the x direction or whose end point position decreases in the x direction so that the line segment extends monotonically in the −x direction, determines the presence or absence of intersection between line segments with the opposite side including the x coordinate of the reference line in the line segment as an intersection determination target, and excludes the remaining line segments from intersection determination targets with respect to the reference line. In this manner, the number of intersection determinations can be significantly reduced.

As the reference line setting step (S212), the reference line setting unit 82 sets a reference line in the plane scanning method for the x-monotone polygon. The example shown in FIG. 18 shows, for example, a case where the line segment 9-10 extending sequentially in the −x direction is set as a reference line.

As the overlapping line segment extraction step (S214), the extraction unit 84 extracts line segments that may intersect with the reference line. In the x-monotone polygon, among the line segments extending in a direction opposite to the direction in which the reference line extends, only line segments whose x coordinates overlap the x coordinates of the reference line are extracted. In the example shown in FIG. 18, the x coordinates of two line segments of the line segment 2-3 and the line segment 3-4 overlap the x coordinates of the line segment 9-10.

As the two line segments intersection determination step (S216), the two line segments intersection determination unit 86 performs intersection determination between the reference line and the extracted line segment.

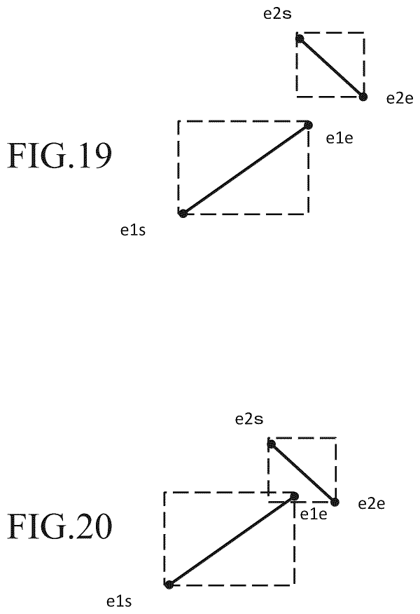

FIG. 19 is a diagram showing an example of circumscribed rectangles of two line segments that are intersection determination targets in the first embodiment.

FIG. 20 is a diagram showing another example of circumscribed rectangles of two line segments that are intersection determination targets in the first embodiment.

First, the two line segments intersection determination unit 86 sets a circumscribed rectangle for each of the two line segments (the reference line and the extracted line segment) that are intersection determination targets. In the example shown in FIG. 19, a circumscribed rectangle whose diagonals are the start point e1s and the end point e1e of a line segment e1 and a circumscribed rectangle whose diagonals are the start point e2s and the end point e2e of a line segment e2 are shown.

The two line segments intersection determination unit 86 calculates whether or not the two set circumscribed rectangles intersect with each other. Specifically, the two circumscribed rectangles do not intersect with each other if any of the following Expressions (1) to (4) is satisfied.
(1) Upper end y coordinate of line segment e1<Lower end y coordinate of line segment e2
(2) Lower end y coordinate of line segment e1>Upper end y coordinate of line segment e2
(3) Left end x coordinate of line segment e1>Right end x coordinate of line segment e2
(4) Right end x coordinate of line segment e1<Left end x coordinate of line segment e2

Therefore, it is calculated whether or not “upper end y coordinate of line segment e1<lower end y coordinate of line segment e2” is satisfied by comparing the upper end y coordinate of the line segment e1 with the lower end y coordinate of the line segment e2. Similarly, it is calculated whether or not “lower end y coordinate of line segment e1>upper end y coordinate of line segment e2” is satisfied by comparing the lower end y coordinate of the line segment e1 with the upper end y coordinate of the line segment e2. Similarly, it is calculated whether or not “left end x coordinate of line segment e1>right end x coordinate of line segment e2” is satisfied by comparing the left end x coordinate of the line segment e1 with the right end x coordinate of the line segment e2. Similarly, it is calculated whether or not “right end x coordinate of line segment e1<left end x coordinate of line segment e2” is satisfied by comparing the right end x coordinate of the line segment e1 with the left end x coordinate of the line segment e2.

As shown in FIG. 19, in the case of “upper end y coordinate of line segment e1<lower end y coordinate of line segment e2”, the above Expression (1) is satisfied. Therefore, the two circumscribed rectangles do not intersect with each other.

On the other hand, as shown in FIG. 20, when none of the four Expressions described above are satisfied as in the case of “upper end y coordinate of line segment e1>lower end y coordinate of line segment e2” (above Expression (1) is not satisfied), the case of “lower end y coordinate of line segment e1<upper end y coordinate of line segment e2” (above Expression (2) is not satisfied), the case of “left end x coordinate of line segment e1<right end x coordinate of line segment e2” (above Expression (3) is not satisfied), and the case of “right end x coordinate of line segment e1>left end x coordinate of line segment e2” (above Expression (4) is not satisfied), the two circumscribed rectangles intersect with each other. When the two circumscribed rectangles do not intersect with each other, the two line segments intersection determination unit 86 determines that the two line segments (the reference line and the extracted line segment) that are intersection determination targets do not intersect with each other. Then, the process proceeds to the next step for the case where the two circumscribed rectangles intersect with each other.

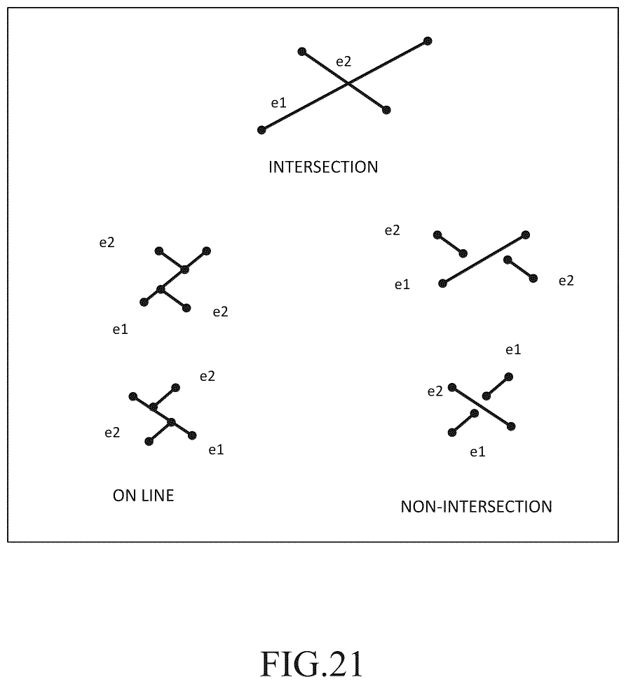

FIG. 21 is a diagram showing an example of the positional relationship between line segments as intersection determination targets in the first embodiment. As shown in FIG. 21, the positional relationship between the line segments as intersection determination targets is one of intersection, non-intersection, and on the line in which the start point or the end point of one line segment is located on the other line segment. When the line segments intersect with each other, the start point and the end point of one line segment are located on the left and right sides with respect to the other line segment. In addition, in the case of non-intersection, both the start point and the end point of one line segment are located on one of the left and right sides with respect to the other line segment.

Therefore, the two line segments intersection determination unit 86 calculates where the start point and the end point of the line segment e1, which is one of the two target line segments (the reference line and the extracted line segment), are located with respect to the other line segment e2 by using a cross product determination method.

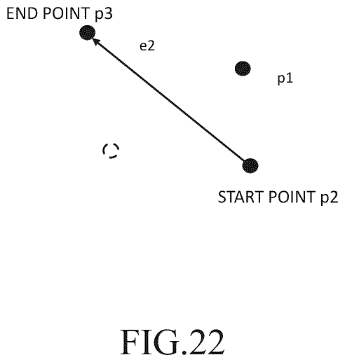

FIG. 22 is a diagram for explaining a method of determining a cross product in the first embodiment. For example, assuming that the start point of the line segment e1 is p1, the two line segments intersection determination unit 86 calculates the position of p1 with respect to the line segment e2 extending from p2 to p3 using the start point p2 of the line segment e2 and the end point p3 of the line segment e2. The position n of p1 with respect to the line segment e2 extending from p2 to p3 can be calculated by the following Equation (5) using the coordinates (p1x, p1y) of p1, the coordinates (p2x, p2y) of p2, and the coordinates (p3x, p3y) of p3.

$$n = ( p 1 x ( p 2 y - p 3 y ) + p 2 x ( p 3 y - p 1 y ) + p 3 x ( p 1 y - p 2 y ) \qquad ( 5 )$$

When n<0, p1 is on the right side of the line segment e2 extending from p2 to p3, when n>0, p1 is on the left side of the line segment e2 extending from p2 to p3, and when n=0, p1 is on the line segment e2 extending from p2 to p3. Similarly, assuming that the end point of the line segment e1 is p1, the two line segments intersection determination unit 86 calculates the position of p1 with respect to the line segment e2 extending from p2 to p3 using the start point p2 of the line segment e2 and the end point p3 of the line segment e2. As a result of the calculation, when the start point and the end point of the line segment e1 are located on the left and right sides with respect to the line segment e2, it is determined that the line segment e1 and the line segment e2 intersect with each other. In addition, even when one of the start point and the end point of the line segment e1 is on the right side of the line segment e2 and the other is on the line segment e2, it is determined that the line segment e1 and the line segment e2 intersect with each other. In other cases, it is determined that the line segment e1 and the line segment e2 do not intersect with each other.

As the determination step (S218), the determination unit 88 determines whether or not there remains any line segment that has not been determined to intersect with the target reference line among the at least one extracted line segment. When there is no line segment, the process proceeds to the determination step (S220). When there is any remaining line segment, the process returns to the overlapping line segment extraction step (S214) to extract the remaining target line segment, and each step of the overlapping line segment extraction step (S214) to the determination step (S218) is repeated until there is no remaining target line segment whose intersection with the target reference line has not been determined.

As the determination step (S220), the determination unit 90 determines whether or not the intersection determination has been completed for all reference lines. When the intersection determination has not been completed for all the reference lines, the process returns to the reference line setting step (S212) to set the next reference line, and each step of the reference line setting step (S212) to the determination step (S220) is repeated until the intersection determination is completed for all the reference lines. In addition, as described above, in the case of an x-monotone polygon, it is sufficient to set only either the line segments sequentially extending in the +x direction or the line segments sequentially extending in the −x direction as the reference lines. In the example shown in FIG. 18, the line segments 1-2, 2-3, 3-4, 4-5, and 5-6 can be mentioned as a plurality of line segments extending sequentially in the +x direction. The line segments 7-8, 8-9, 9-10, and 10-0 can be mentioned as a plurality of line segments extending sequentially in the −x direction.

As the y-monotone polygon intersection determination processing step (S130) in FIG. 9, the intersection determination processing unit 60 performs, for each target figure that is a y-monotone polygon, intersection determination processing according to the y-monotone polygon.

A flowchart showing an example of internal steps of the y-monotone polygon intersection determination processing step (S130) in the first embodiment is similar to FIG. 16.

As the scanning direction setting step (S204) in FIG. 16, the scanning direction setting unit 64 sets a scanning direction in the plane scanning method for the y-monotone polygon to the y direction.

As the line segment list creation step (S206), the line segment list creation unit 66 replaces each line segment of the target figure, which is a y-monotone polygon, in parallel to the set scanning direction. Here, each line segment of the target figure is replaced in parallel to the y direction. In other words, each line segment of the target figure is transformed so as to be projected onto the y-direction axis. As a result, a list of line segments parallel to the y direction is created.

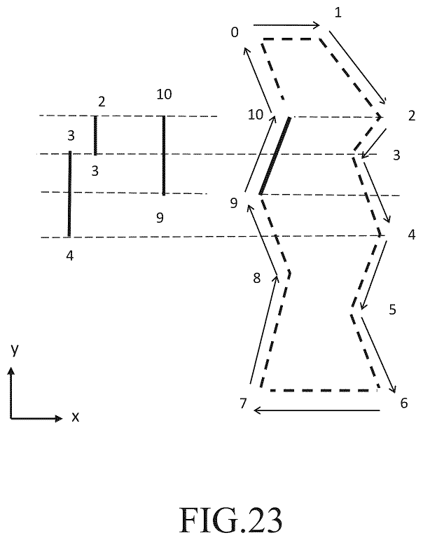

FIG. 23 is a diagram for explaining the plane scanning method using a y-monotone polygon in the first embodiment. In the example in FIG. 23, an example of an 11-sided y-monotone polygon having vertices 0 to 10 is shown. In the example shown in FIG. 23, nine line segments 1-2, 2-3, 3-4, 4-5, 5-6, 7-8, 8-9, 9-10, and 10-0 parallel to the y direction are defined in the list. The line segments 0-1 and 6-7 are points, and there are no line segments parallel to the y direction.

As described above, the y-monotone polygon is formed by a plurality of line segments in which each line segment between vertices extends sequentially in the +y direction and then returns sequentially in the −y direction. Alternatively, the y-monotone polygon is formed by a plurality of line segments that extend sequentially in the −y direction and then returns sequentially in the +y direction. The example in FIG. 23 shows a case where the line segment is formed by a plurality of line segments that extend sequentially in the −y direction and then return sequentially in the +y direction.

Therefore, line segments that monotonically extend sequentially in the +y direction do not intersect with each other. Similarly, line segments that monotonically extend sequentially in the −y direction do not intersect with each other. Therefore, line segments that may intersect with each of the line segments extending sequentially in the +y direction are only line segments whose y coordinates overlap each of the line segments extending sequentially in the +y direction among the line segments extending sequentially in the −y direction. Similarly, line segments that may intersect with each of the line segments extending sequentially in the −y direction are only line segments whose y coordinates overlap each of the line segments extending sequentially in the −y direction among the line segments extending sequentially in the +y direction. Therefore, it is sufficient to perform intersection determination by using only each line segment extending in one direction, among the line segments extending sequentially in the +y direction and the line segments extending sequentially in the −y direction, as a reference line.

Therefore, when the shape of the figure is a y-monotone polygon as a result of the shape determination, the intersection determination processing unit 60 sets, as a reference line, a line segment whose end point position increases in the y direction so that the line segment extends monotonically in the y direction or whose end point position decreases in the y direction so that the line segment extends monotonically in the −y direction, determines the presence or absence of intersection between line segments with the opposite side including the y coordinate of the reference line in the line segment as an intersection determination target, and excludes the remaining line segments from intersection determination targets with respect to the reference line. In this manner, the number of intersection determinations can be significantly reduced.

As the reference line setting step (S212), the reference line setting unit 82 sets a reference line in the plane scanning method for the y-monotone polygon. In the example shown in FIG. 23 shows, for example, a case where the line segment 9-10 extending sequentially in the +y direction is set as a reference line.

As the overlapping line segment extraction step (S214), the extraction unit 84 extracts line segments that may intersect with the reference line. In the y-monotone polygon, among the line segments extending in a direction opposite to the direction in which the reference line extends, only line segments whose y coordinates overlap the y coordinates of the reference line are extracted. In the example shown in FIG. 23, the y coordinates of two line segments of the line segment 2-3 and the line segment 3-4 overlap the y coordinates of the line segment 9-10.

As the two line segments intersection determination step (S216), the two line segments intersection determination unit 86 performs intersection determination between the reference line and the extracted line segment. The method for intersection determination is the same as in the case of the x-monotone polygon.

The contents of the determination step (S218) and the determination step (S220) for the y-monotone polygon are the same as for the x-monotone polygon. In addition, as described above, in the case of a y-monotone polygon, it is sufficient to set only either the line segments sequentially extending in the +y direction or the line segments sequentially extending in the −y direction as the reference lines. In the example shown in FIG. 23, the line segments 1-2, 2-3, 3-4, 4-5, and 5-6 can be mentioned as a plurality of line segments extending sequentially in the −y direction. The line segments 7-8, 8-9, 9-10, and 10-0 can be mentioned as a plurality of line segments extending sequentially in the +y direction.

As the non-monotone polygon intersection determination processing step (S140) in FIG. 9, the intersection determination processing unit 60 performs, for each target figure that is a non-monotone polygon, intersection determination processing according to the non-monotone polygon. When the shape of the figure is a polygon (non-monotone polygon) that is neither an x-monotone polygon nor a y-monotone polygon as a result of the shape determination, the intersection determination processing unit 60 calculates the displacement direction of the x coordinate and the displacement direction of the y coordinate of the next vertex from the position of the previous vertex for each of a plurality of vertices forming the non-monotone polygon, and determines the presence or absence of intersection between line segments by using one of the x direction and the y direction as a scanning direction, the number of vertices whose displacement directions change from the positive direction to the negative direction or from the negative direction to the positive direction in the one direction being smaller than that in the other direction. Hereinafter, a specific description will be given.

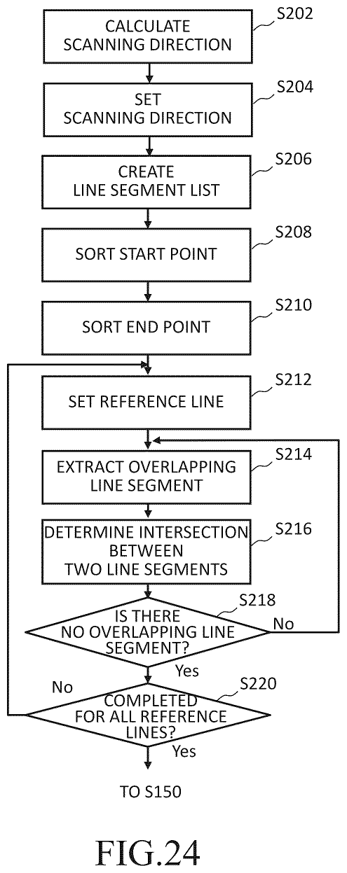

FIG. 24 is a flowchart showing an example of internal steps of the non-monotone polygon intersection determination processing step in the first embodiment. In FIG. 24, in the non-monotone polygon intersection determination processing step (S140), a series of steps including a scanning direction calculation step (S202), a scanning direction setting step (S204), a line segment list creation step (S206), a start point sorting step (S208), an end point sorting step (S210), a reference line setting step (S212), an overlapping line segment extraction step (S214), a two line segments intersection determination step (S216), a determination step (S218), and a determination step (S220) are performed as internal steps.

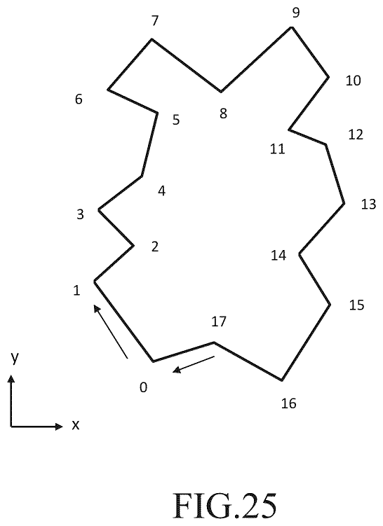

FIG. 25 is a diagram showing an example of a non-monotone polygon in the first embodiment. In the example in FIG. 25, an example of an 18-sided non-monotone polygon having vertices 0 to 17 is shown. In the case of a non-monotone polygon, as described above, the number of times of intersection determination processing differs depending on whether or not the scanning direction is the x direction or the y direction. For this reason, in the first embodiment, a direction in which the number of times of intersection determination processing is decreased is calculated.

As the scanning direction calculation step (S202), the scanning direction calculation unit 62 calculates the displacement direction of the x coordinate and the displacement direction of the y coordinate of the next vertex from the position of the previous vertex for each of a plurality of vertices forming the non-monotone polygon.

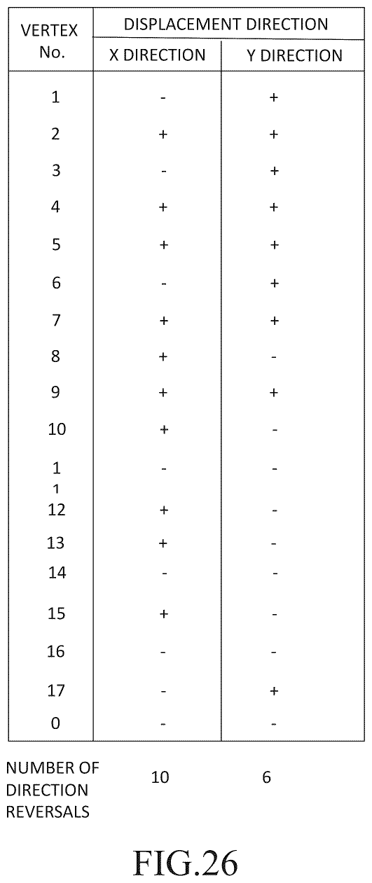

FIG. 26 is a table showing an example of the displacement direction of the x coordinate and the displacement direction of the y coordinate in the first embodiment. In the example shown in FIG. 26, for the 18-sided non-monotone polygon having vertices 0 to 17 shown in FIG. 25, the displacement direction of the x coordinate and the displacement direction of the y coordinate from the vertex 0 to the vertex 1 are indicated as the vertex 1. The displacement direction of the x coordinate and the displacement direction of the y coordinate from the vertex 1 to the vertex 2 are indicated as the vertex 2. Thereafter, similarly, the displacement direction of the x coordinate and the displacement direction of the y coordinate from the vertex 17 to the vertex 0 are indicated as the vertex 0. As shown in FIGS. 25 and 26, for example, the displacement amount of the x coordinate from the vertex 0 to the vertex 1 is an amount in the negative direction. Therefore, the displacement direction is negative (−). The displacement amount of the x coordinate from the vertex 1 to the vertex 2 is an amount in the positive direction. Therefore, the displacement direction is positive (+). Thereafter, similarly, displacement amounts up to the displacement amount of the x coordinate from the vertex 17 to the vertex 0 are calculated. The displacement amount of the x coordinate from the vertex 17 to the vertex 0 is an amount in the negative direction. Therefore, the displacement direction is negative.

For example, the displacement amount of the y coordinate from the vertex 0 to the vertex 1 is an amount in the positive direction. Therefore, the displacement direction is positive. The displacement amount of the y coordinate from the vertex 1 to the vertex 2 is an amount in the positive direction. Therefore, the displacement direction is positive. Thereafter, similarly, displacement amounts up to the displacement amount of the y coordinate from the vertex 17 to the vertex 0 are calculated. The displacement amount of the y coordinate from the vertex 17 to the vertex 0 is an amount in the negative direction. Therefore, the displacement direction is negative.

Then, the scanning direction calculation unit 62 calculates the number of vertices whose displacement directions change from the positive direction to the negative direction or from the negative direction to the positive direction in one of the x direction and the y direction. In the example shown in FIG. 25, as shown in FIG. 26, the number of vertices whose displacement directions are reversed from the positive direction to the negative direction or from the negative direction to the positive direction in the x direction is ten. Similarly, the number of vertices whose displacement directions are reversed from the positive direction to the negative direction or from the negative direction to the positive direction in the y direction is six.

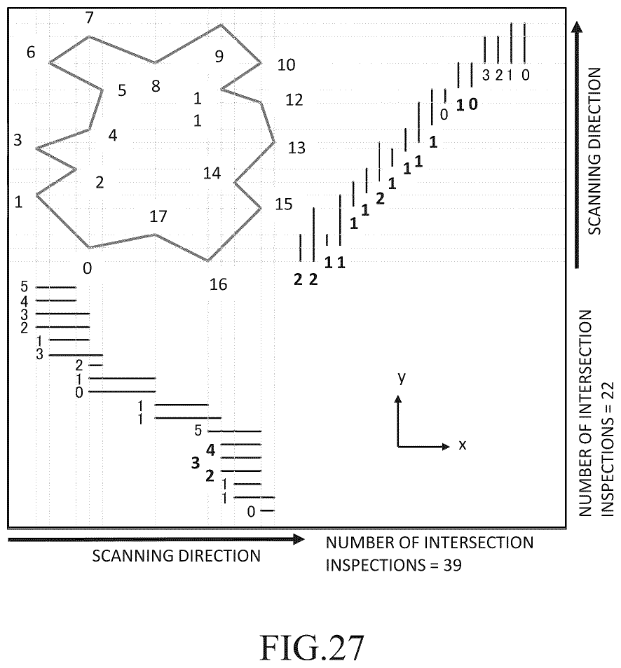

FIG. 27 is a diagram showing an example of the number of intersection determinations in the x direction and the y direction in the first embodiment. In the example shown in FIG. 27, for the 18-sided non-monotone polygon having vertices 0 to 17 shown in FIG. 25, the number of intersection determinations when the x direction is the scanning direction and the number of intersection determinations when the y direction is the scanning direction are shown. The number shown in each line segment parallel to the x direction or the y direction between the vertices of the 18-sided polygon in FIG. 27 indicates the number of intersection determinations when the target line segment is used as a reference line. As shown in FIG. 27, the total number of intersection determinations when the x direction is a scanning direction is 39, while the total number of intersection determinations when the y direction is a scanning direction is only 22. Thus, when performing the intersection determination processing using the plane scanning method, as in the cases described in FIGS. 7 and 8, it is better to set the direction with fewer reversals in displacement direction as a scanning direction because it is possible to reduce the number of times of intersection determination processing.

Therefore, the scanning direction calculation unit 62 calculates one of the x direction and the y direction as a scanning direction, the number of vertices whose displacement directions change from the positive direction to the negative direction or from the negative direction to the positive direction in the one direction being smaller than that in the other direction. In the example shown in FIG. 25, the y direction is calculated as a scanning direction because the number of vertices whose displacement directions change from the positive direction to the negative direction or from the negative direction to the positive direction in the y direction is smaller than that in the x direction. By selecting the direction with fewer reversals in displacement direction as a scanning direction, it is possible to reduce the number of intersection determinations.

As the scanning direction setting step (S204), the scanning direction setting unit 64 sets a scanning direction in the plane scanning method for the non-monotone polygon. In the case of a non-monotone polygon, the scanning direction setting unit 64 sets the calculated direction as a scanning direction. In the example shown in FIG. 25, the y direction is set as a scanning direction.

As the line segment list creation step (S206), the line segment list creation unit 66 replaces each line segment of the target figure, which is a non-monotone polygon, in parallel to the set scanning direction. In other words, each line segment of the target figure is transformed so as to be projected onto the axis in the set scanning direction. As a result, a list of line segments parallel to the set scanning direction is created. In the example shown in FIG. 25, each line segment of the target figure is replaced in parallel to the y direction. As a result, a list of line segments parallel to the y direction is created.

As the start point sorting step (S208), the start point sorting unit 68 sorts the created line segment list in the order of the start points of the line segments.

As the end point sorting step (S210), the end point sorting unit 80 sorts the created line segment list in the order of the end points of the line segments for line segments whose start points are the same.

As a result, it is possible to perform rearrangement like a plurality of line segments with the y direction as a scanning direction in FIG. 27.

As the reference line setting step (S212), the reference line setting unit 82 sets a reference line in the plane scanning method for the non-monotone polygon. Since the line segment list has been sorted, setting as a reference line is made in order from the line segment with the smallest start point in the scanning direction. In addition, when the start points are the same, setting as a reference line is made in order from the line segment with the smallest end point in the scanning direction. In the example shown in FIG. 27, the line segment 16-17 is first set as a reference line. Then, the line segment 15-16 is set. Then, the line segment 17-0 is set. Then, the line segment 0-1 is set. Thereafter, the settings are similarly made in order.

As the overlapping line segment extraction step (S214), the extraction unit 84 extracts line segments that may intersect with the reference line. In the example shown in FIG. 27, assuming that the line segment 16-17 is a reference line, the line segment 15-16, the line segment 17-0, and the line segment 0-1 are to be extracted.

As the two line segments intersection determination step (S216), the two line segments intersection determination unit 86 performs intersection determination between the reference line and the extracted line segment. The method for intersection determination is the same as in the case of the x-monotone polygon.

The contents of the determination step (S218) and the determination step (S220) for the non-monotone polygon are the same as for the x-monotone polygon. In addition, in the case of a non-monotone polygon, along the sorted line segment list, a line segment that is likely to intersect with a line segment on the downstream side (on the right side in the example shown in FIG. 27) of the target reference line is extracted. For example, assuming that the line segment 15-16 is a reference line, the line segment 17-0 and the line segment 0-1 are to be extracted without extracting the line segment 16-17 on the upstream side of the list. Similarly, for example, assuming that the line segment 17-0 is a reference line, the line segment 0-1 is to be extracted without extracting the line segment 16-17 and the line segment 15-16 on the upstream side of the list. Similarly, assuming that the line segment 0-1 is a reference line, the line segment 14-15 is to be extracted. Thereafter, line segments to be extracted with respect to the target reference line are similarly extracted.

As described above, in the case of a non-monotone polygon, the number of times of intersection determination processing can be reduced by setting the direction with fewer reversals in displacement direction as a scanning direction. As a result, the processing time can be shortened.

As the determination step (S150) in FIG. 9, the determination unit 92 determines whether or not there are line segments intersecting with each other in the target figure. When there are line segments intersecting with each other in the target figure, the process proceeds to the intersection storage step (S152). When there are no line segments intersecting with each other in the target figure, the process proceeds to the determination step (S154).

As the intersection storage step (S152), first, the intersection calculation unit 94 calculates an intersection point between the line segments that intersect with each other. Then, the data storage unit 96 stores information on the figure, the pair of line segments that intersect with each other, and the coordinates of the intersection point in, for example, the storage device 142 or a storage device (not shown) in the intersection determination processing unit 60.

As the determination step (S154), the determination unit 98 determines whether or not the intra-figure line segment intersection determination has been completed for all pieces of figure data in the writing data. When the intra-figure line segment intersection determination has not been completed for all pieces of figure data, the process returns to the figure selection step (S102) and each step of the figure selection step (S102) to the determination step (S154) is repeated until the intra-figure line segment intersection determination is completed for all pieces of figure data.

When the intra-figure line segment intersection determination has been completed for all pieces of figure data, the result of the intra-figure line segment intersection determination is output. As a result, information indicating that there are no line segments intersecting with each other is output, or the information stored in the intersection storage step (S152) is output when there are line segments intersecting with each other.

When there are line segments intersecting with each other among the plurality of pieces of figure data in the writing data, the start of the writing processing is canceled to correct the data of the figure having the line segments intersecting with each other. Then, the corrected writing data is input to the writing apparatus 100 and stored in the storage device 140. When there are no line segments intersecting with each other, the writing data is used as it is for the writing processing. The correction of the figure data may be performed outside the writing apparatus 100 or may be performed within the writing apparatus 100.

Here, in the above-described figure shape determination processing step (S106), it is preferable to perform determination regarding a monotone polygon using the following method.

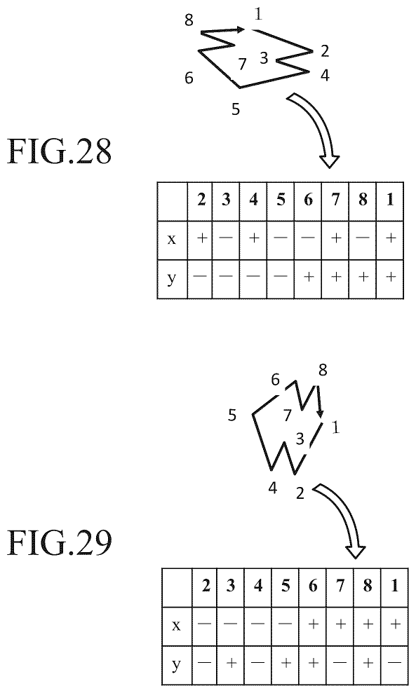

FIG. 28 is a diagram showing an example of a y-monotone polygon in a modification example of the first embodiment.

FIG. 29 is a diagram showing an example of an x-monotone polygon in a modification example of the first embodiment.

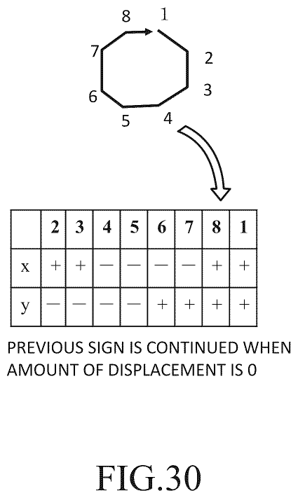

FIG. 30 is a diagram showing an example of an xy-monotone polygon in a modification example of the first embodiment.

In all of the examples shown in FIGS. 28 to 30, an octagon having vertices 1 to 8 is shown. In the modification example of the first embodiment, the displacement direction from the previous vertex to the next vertex is calculated as in the case of the non-monotone polygon described above. In addition, in each of the tables shown in FIGS. 28 to 30, the displacement direction is defined for the vertex after displacement. In addition, when the amount of displacement in the x direction or the y direction is zero, the previous sign (direction) is continued.

In the example shown in FIG. 28, in the x direction, the displacement direction from the vertex 1 to the vertex 2 is positive, the displacement direction from the vertex 2 to the vertex 3 is negative, the displacement direction from the vertex 3 to the vertex 4 is positive, the displacement direction from the vertex 4 to the vertex 5 is negative, the displacement direction from the vertex 5 to the vertex 6 is negative, the displacement direction from the vertex 6 to the vertex 7 is positive, the displacement direction from the vertex 7 to the vertex 8 is negative, and the displacement direction from the vertex 8 to the vertex 1 is positive.

On the other hand, in the y direction, the displacement direction from the vertex 1 to the vertex 2, the displacement direction from the vertex 2 to the vertex 3, the displacement direction from the vertex 3 to the vertex 4, and the displacement direction from the vertex 4 to the vertex 5 are negative, and the displacement direction from the vertex 5 to the vertex 6, the displacement direction from the vertex 6 to the vertex 7, the displacement direction from the vertex 7 to the vertex 8, and the displacement direction from the vertex 8 to the vertex 1 are positive.

The figure in which negative (or positive) continues and then positive (or negative) continues as in the y direction can be determined to be a y-monotone polygon. In addition, when each of both the directions does not continue as in the x direction, the figure is not an x-monotone polygon.

In addition, depending on the method of setting the vertex number, there may be a figure in which, in the x direction, negative (or positive) continues, then positive (or negative) continues, and then negative (or positive) continues. Even in such a case, the figure can be determined to be an x-monotone polygon.

In the example shown in FIG. 29, in the y direction, the displacement direction from the vertex 1 to the vertex 2 is negative, the displacement direction from the vertex 2 to the vertex 3 is positive, the displacement direction from the vertex 3 to the vertex 4 is negative, the displacement direction from the vertex 4 to the vertex 5 is positive, the displacement direction from the vertex 5 to the vertex 6 is positive, the displacement direction from the vertex 6 to the vertex 7 is negative, the displacement direction from the vertex 7 to the vertex 8 is positive, and the displacement direction from the vertex 8 to the vertex 1 is negative.

On the other hand, in the x direction, the displacement direction from the vertex 1 to the vertex 2, the displacement direction from the vertex 2 to the vertex 3, the displacement direction from the vertex 3 to the vertex 4, and the displacement direction from the vertex 4 to the vertex 5 are negative, and the displacement direction from the vertex 5 to the vertex 6, the displacement direction from the vertex 6 to the vertex 7, the displacement direction from the vertex 7 to the vertex 8, and the displacement direction from the vertex 8 to the vertex 1 are positive.

The figure in which negative (or positive) continues and then positive (or negative) continues as in the x direction can be determined to be an x-monotone polygon. In addition, when each of both the directions does not continue as in the y direction, the figure is not a y-monotone polygon.

In addition, depending on the method of setting the vertex number, there may be a figure in which, in the y direction, negative (or positive) continues, then positive (or negative) continues, and then negative (or positive) continues. Even in such a case, the figure can be determined to be a y-monotone polygon.

In the example shown in FIG. 30, in the x direction, the displacement direction from the vertex 1 to the vertex 2 is positive, the displacement direction from the vertex 2 to the vertex 3 is positive, the displacement direction from the vertex 3 to the vertex 4 is negative, the displacement direction from the vertex 4 to the vertex 5 is negative, the displacement direction from the vertex 5 to the vertex 6 is negative, the displacement direction from the vertex 6 to the vertex 7 is negative, the displacement direction from the vertex 7 to the vertex 8 is positive, and the displacement direction from the vertex 8 to the vertex 1 is positive.

In addition, in the y direction, the displacement direction from the vertex 1 to the vertex 2, the displacement direction from the vertex 2 to the vertex 3, the displacement direction from the vertex 3 to the vertex 4, and the displacement direction from the vertex 4 to the vertex 5 are negative, and the displacement direction from the vertex 5 to the vertex 6, the displacement direction from the vertex 6 to the vertex 7, the displacement direction from the vertex 7 to the vertex 8, and the displacement direction from the vertex 8 to the vertex 1 are positive.

Thus, the figure in which negative (or positive) continues and then positive (or negative) continues as in the x and y directions can be determined to be an xy-monotone polygon.

In addition, depending on the method of setting the vertex number, there may be a figure in which, in at least one of the x and y directions, negative (or positive) continues, then positive (or negative) continues, and then negative (or positive) continues. Even in such a case, the figure can be determined to be an xy-monotone polygon. The x direction in FIG. 30 is an example of this.

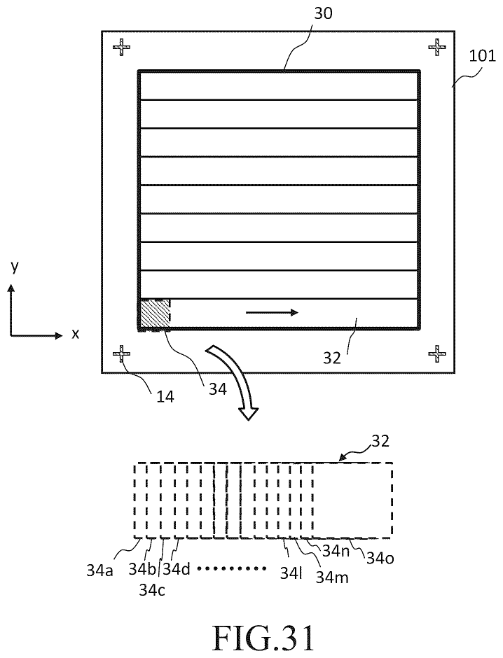

FIG. 31 is a conceptual diagram for explaining an example of a writing operation in the first embodiment. As shown in FIG. 31, the position of a writing region 30 (thick line) of the target object 101 is defined based on the position of an alignment mark 14.

The writing region 30 (thick line) is virtually divided into a plurality of striped regions 32 having a predetermined width in the y direction, for example. The example in FIG. 31 shows a case where the writing region 30 of the target object 101 is divided into the plurality of striped regions 32, for example, in the y direction, with the substantially the same width as the size of a designed irradiation region 34 (writing field) that can be irradiated with one-time multiple beams 20. The size of the designed irradiation region 34 of the multiple beams 20 in the x direction can be defined as the number of beams in the x direction x the pitch between beams in the x direction. The size of the rectangular irradiation region 34 in the y direction can be defined as the number of beams in the y direction x the pitch between beams in the y direction.

First, the XY stage 105 is moved to make an adjustment so that the irradiation region 34 of the multiple beams 20 is located at the left end of the first striped region 32 or further to the left, and the first striped region 32 is written. When writing the first striped region 32, the XY stage 105 is moved, for example, in the −x direction, so that the writing proceeds relatively in the x direction. The XY stage 105 is continuously moved, for example, at a constant speed. After writing the first striped region 32, the stage position is moved in the −y direction by the width of the striped region 32.

Then, an adjustment is made so that the irradiation region 34 of the multiple beams 20 is located at the left end of the second striped region 32 or further to the left, and the XY stage 105 is moved, for example, in the −x direction so that the writing proceeds relatively in the x direction. In this manner, the second striped region 32 is written.

In addition, although the example in FIG. 31 shows a case where the writing in each striped region 32 proceeds in the same direction, the present invention is not limited thereto. For example, for the striped region 32 where writing is to be performed next to the striped region 32 where writing has been performed in the x direction, the writing may be performed in the −x direction by moving the XY stage 105, for example, in the x direction. By performing writing while alternately changing the direction in this manner, the stage movement time can be shortened, and the writing time can be shortened. In one shot, by the multiple beams 20 formed by passing through each hole 22 of the shaping aperture array substrate 203, a plurality of shot patterns, up to the same number as each hole 22, are formed at a time.

In addition, although the example in FIG. 31 shows a case where the stage movement for writing in each striped region is performed once at a time, the present invention is not limited thereto. It is also preferable to perform multi-writing so that the stage moves multiple times on the same position. In this case, for example, it is preferable to perform multi-writing while shifting in the y direction by a shift amount of 1/n of the width of the striped region.

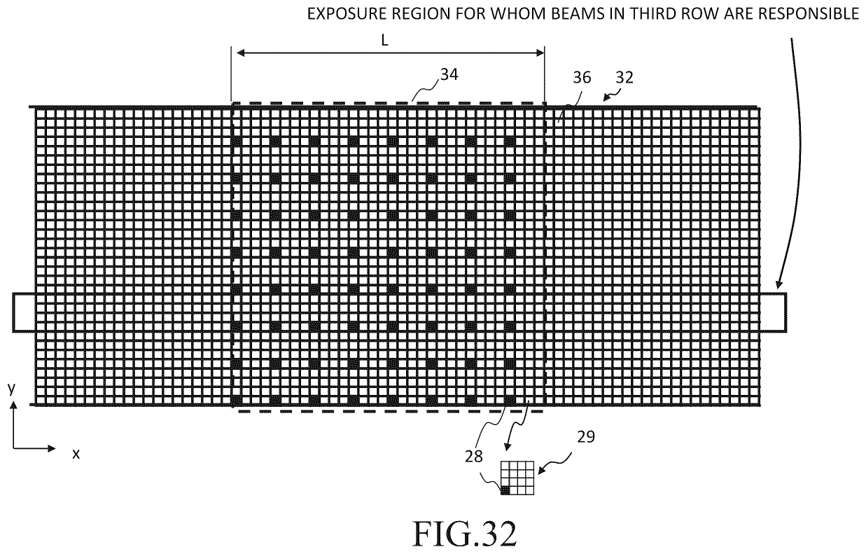

FIG. 32 is a diagram showing an example of a multiple beams irradiation region and writing target pixels in the first embodiment. In FIG. 32, the striped region 32 is divided into a plurality of mesh regions with the beam size of the multiple beams 20, for example. Each of such mesh regions is a writing target pixel 36 (unit irradiation region, irradiation position, or writing position). The size of the writing target pixel 36 is not limited to the beam size, and may be any size regardless of the beam size. For example, the size of the writing target pixel 36 may be 1/n (n is an integer of 1 or more) of the beam size. The example in FIG. 32 shows a case where the writing region of the target object 101 is divided into a plurality of striped regions 32, for example, in the y direction, with the substantially the same width as the size of the irradiation region 34 (writing field) that can be irradiated with one-time multiple beams 20. The size of the rectangular irradiation region 34 in the x direction can be defined as the number of beams in the x direction x the pitch between beams in the x direction. The size of the rectangular irradiation region 34 in the y direction can be defined as the number of beams in the y direction x the pitch between beams in the y direction. In the example shown in FIG. 32, for example, 512×512 columns of multiple beams are abbreviated to 8×8 columns of multiple beams. Then, in the irradiation region 34, a plurality of pixels 28 (beam lithography positions) that can be irradiated with one shot of the multiple beams 20 are shown. The pitch between the pixels 28 adjacent to each other is the pitch between the multiple beams. A rectangular region surrounded with the size of the beam pitch in the x and y directions is one sub-irradiation region 29 (pitch cell). The example in FIG. 32 shows a case where each sub-irradiation region 29 is formed by, for example, 4×4 pixels.

As a shot data generation step, first, the shot data generation unit 70 generates shot data for each pixel 36. Specifically, the shot data generation unit 70 operates as follows. First, the shot data generation unit 70 reads writing data from the storage device 140 and calculates a pattern area density ρ′ within the pixel 36 for each pixel 36. Such processing is performed for each striped region 32, for example.

Then, the shot data generation unit 70 first virtually divides the writing region (here, for example, the striped region 32) into a plurality of proximity mesh regions (mesh regions for proximity effect correction calculation) in a mesh form with a predetermined size. The size of the proximity mesh region is preferably set to about 1/10 of the influence range of the proximity effect, for example, about 1 μm. The shot data generation unit 70 reads writing data from the storage device 140 and calculates, for each proximity mesh region, a pattern area density ρ″ of a pattern arranged in the proximity mesh region.

Then, the shot data generation unit 70 calculates a proximity effect correction dose coefficient Dp(x) (corrected doses) for correcting the proximity effect for each proximity mesh region. The unknown proximity effect correction dose coefficient Dp(x) can be defined by a threshold model for proximity effect correction that is similar to the conventional method and uses a back scattering coefficient η, a threshold dose Dth of the threshold model, a pattern area density ρ″, and a distribution function g(x).

Then, the shot data generation unit 70 calculates, for each pixel 36, incident doses of the beam D(x) (dose) for irradiating the pixel 36. The incident doses of the beam D(x) may be calculated, for example, as a value obtained by multiplying the base doses of the beam Dbase by the proximity effect correction dose coefficient Dp and the pattern area density ρ′. The base doses of the beam Dbase can be defined as Dth/(½+η), for example. As described above, it is possible to obtain the incident doses of the beam D(x) for each pixel 36 with the proximity effect corrected, based on the layout of a plurality of figures defined in the writing data.

Then, the shot data generation unit 70 calculates the beam irradiation time for each pixel 36. The beam irradiation time for each pixel 36 can be calculated by dividing the incident doses of the beam D(x) of the pixel by the current density J.

As a data processing step, the data processing unit 72 rearranges the obtained beam irradiation time data for each pixel 36 in shot order and stores the irradiation time data in the storage device 142. The transfer processing unit 74 transfers the beam irradiation time data to the deflection control circuit 130 in shot order.

As a writing step, under the control of the writing control unit 76, the writing mechanism 150 writes a pattern on the target object 101 on the XY stage 105 using the multiple beams 20 while moving the XY stage 105. In the multiple beams writing, shot data of a region to be subjected to writing processing later is generated in parallel while performing writing processing. For example, shot data for the (k+2)-th striped region 32 is generated in parallel while writing the k-th striped region 32. While repeating this operation, all of the striped regions 32 are written.

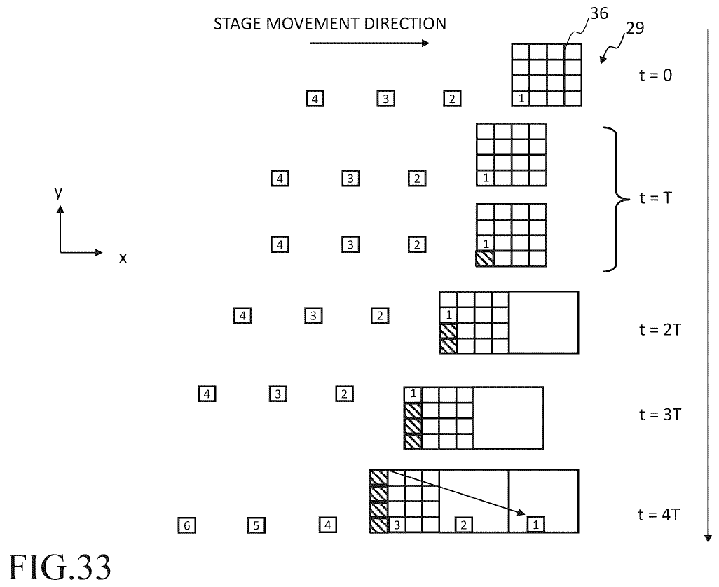

FIG. 33 is a diagram for explaining an example of a multiple beams writing operation in the first embodiment. The example in FIG. 33 shows a case where each sub-irradiation region 29 including one beam irradiation position of the multiple beams 20 and surrounded with the pitch between beams is written with four different beams. In addition, the example shown in FIG. 33 shows a writing operation in which the XY stage 105 moves continuously at a speed for movement by a distance of two beam pitches, for example, while writing a ¼ region (1/the number of beams used for irradiation) in each sub-irradiation region 29. The example in FIG. 33 shows a case where each sub-irradiation region 29 is formed by, for example, 4×4 pixels.

In the writing operation shown in the example of FIG. 33, for example, four different pixels 36 within the same sub-irradiation region 29 are written (exposed) by performing four shots of the multiple beams 20 with a shot cycle T while shifting the irradiation position (pixel 36) sequentially by the deflector 209 during the movement of the XY stage 105 by a distance of two beam pitches in the x direction. The irradiation region 34 is caused to follow the movement of the XY stage 105 by collectively deflecting all of the multiple beams 20 with the deflector 208, so that the relative position of the irradiation region 34 with respect to the target object 101 does not shift due to the movement of the XY stage 105, while writing (exposing) the four pixels 36. In other words, tracking control is performed. When one tracking cycle ends, the tracking is reset to return to the previous tracking start position. In addition, since the writing of the first pixel column from the left of each sub-irradiation region 29 has been completed, in the next tracking cycle after tracking reset, the deflector 209 first performs deflection to match (shift) the writing position of the beam, which is different from the first pixel column, so as to write, for example, the second pixel column from the left that has not yet been written in each sub-irradiation region 29. By repeating this operation while writing the striped region 32, the position of the irradiation region 34 (34a to 34o) of the multiple beams 20 is sequentially moved as shown in the lower diagram of FIG. 31 to perform writing.

As described above, according to the first embodiment, it is possible to efficiently determine the intersection of line segments within a figure of polygonal figure data defined in writing data. Therefore, it is possible to shorten the time required for intersection determination.

The embodiment has been described above with reference to the specific examples. However, the present invention is not limited to the specific examples.

In addition, a computer may be caused to execute the processing described in the first embodiment. Then, a program for causing a computer to execute such processing may be stored, for example, in a non-transitory computer-readable storage medium such as a magnetic disk drive.

In addition, the description of parts that are not directly required for the description of the present invention, such as the apparatus configuration or the control method, is omitted. However, the required apparatus configuration or control method can be appropriately selected and used. For example, although the description of the control unit configuration for controlling the writing apparatus 100 is omitted, it is needless to say that the required control unit configuration can be appropriately selected and used.

In addition, all methods for determining line segment intersections in a figure of writing data that include the elements of the present invention and whose design can be modified as appropriate by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for determining line segment intersections in a figure of writing data, comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein in a case that the shape of the figure is an xy-monotone polygon and a convex polygon as a result of the shape determination, the intersection determination processing is omitted.

2. A method for determining line segment intersections in a figure of writing data, comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is an x-monotone polygon as a result of the shape determination, a line segment having an end point with a position increasing in the x direction so that the line segment extends monotonically in the x direction or having an end point with a position decreasing in the x direction so that the line segment extends monotonically in the −x direction is set as a reference line, presence or absence of intersection between line segments is determined with an opposite side including an x coordinate of the reference line in a line segment as an intersection determination target, and remaining line segments are excluded from intersection determination targets with respect to the reference line.

3. A method for determining line segment intersections in a figure of writing data, comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a y-monotone polygon as a result of the shape determination, a line segment having an end point with a position increasing in the y direction so that the line segment extends monotonically in the y direction or having an end point with a position decreasing in the y direction so that the line segment extends monotonically in the −y direction is set as a reference line, presence or absence of intersection between line segments is determined with an opposite side including a y coordinate of the reference line in a line segment as an intersection determination target, and remaining line segments are excluded from intersection determination targets with respect to the reference line.

4. A method for determining line segment intersections in a figure of writing data, comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a polygon as neither an x-monotone polygon nor a y-monotone polygon as a result of the shape determination, a displacement direction of an x coordinate and a displacement direction of a y coordinate of a next vertex from a position of a previous vertex are calculated for each of a plurality of vertices forming the polygon, and presence or absence of intersection between line segments is determined by using one of the x direction and the y direction as a scanning direction, the number of vertices with displacement directions changing from a positive direction to a negative direction or from the negative direction to the positive direction in the one direction being smaller than that in the other direction.

5. The method according to claim 1,
wherein the performing of the intersection determination processing includes:
when the shape of the figure is a non-monotone polygon as a result of the shape determination, replacing each line segment of a target figure as the non-monotone polygon in parallel to a predetermined scanning direction and creating a list of line segments parallel to a scanning direction;
sorting a created line segment list; and
extracting a line segment likely to intersect with a predetermined reference line.

6. The method according to claim 2,
wherein the performing of the intersection determination processing includes:
when the shape of the figure is a non-monotone polygon as a result of the shape determination, replacing each line segment of a target figure as the non-monotone polygon in parallel to a predetermined scanning direction and creating a list of line segments parallel to a scanning direction;
sorting a created line segment list; and
extracting a line segment likely to intersect with a predetermined reference line.

7. The method according to claim 3,
wherein the performing of the intersection determination processing includes:
when the shape of the figure is a non-monotone polygon as a result of the shape determination, replacing each line segment of a target figure as the non-monotone polygon in parallel to a predetermined scanning direction and creating a list of line segments parallel to a scanning direction;
sorting a created line segment list; and
extracting a line segment likely to intersect with a predetermined reference line.

8. The method according to claim 4,
wherein the performing of the intersection determination processing includes:
when the shape of the figure is a non-monotone polygon as a result of the shape determination, replacing each line segment of a target figure as the non-monotone polygon in parallel to a predetermined scanning direction and creating a list of line segments parallel to a scanning direction;
sorting a created line segment list; and
extracting a line segment likely to intersect with a predetermined reference line.

9. The method according to claim 1, further comprising:
storing, for line segments intersecting with each other as a result of the intersection determination, information on a figure, a pair of line segments intersecting with each other, and intersection coordinates in a storage device.

10. The method according to claim 2, further comprising:
storing, for line segments intersecting with each other as a result of the intersection determination, information on a figure, a pair of line segments intersecting with each other, and intersection coordinates in a storage device.

11. The method according to claim 3, further comprising:
storing, for line segments intersecting with each other as a result of the intersection determination, information on a figure, a pair of line segments intersecting with each other, and intersection coordinates in a storage device.

12. The method according to claim 4, further comprising:
storing, for line segments intersecting with each other as a result of the intersection determination, information on a figure, a pair of line segments intersecting with each other, and intersection coordinates in a storage device.

13. An apparatus for determining line segment intersections in a figure of writing data, comprising:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is an xy-monotone polygon and a convex polygon as a result of the shape determination, the intersection determination processing is omitted.

14. An apparatus for determining line segment intersections in a figure of writing data, comprising:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is an x-monotone polygon as a result of the shape determination, the intersection determination processing circuit sets, as a reference line, a line segment having an end point with a position increasing in the x direction so that the line segment extends monotonically in the x direction or having an end point with a position decreasing in the x direction so that the line segment extends monotonically in the −x direction, determines presence or absence of intersection between line segments with an opposite side including an x coordinate of the reference line in a line segment as an intersection determination target, and excludes remaining line segments from intersection determination targets with respect to the reference line.

15. An apparatus for determining line segment intersections in a figure of writing data, comprising:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is a y-monotone polygon as a result of the shape determination, the intersection determination processing circuit sets, as a reference line, a line segment having an end point with a position increasing in the y direction so that the line segment extends monotonically in the y direction or having an end point with a position decreasing in the y direction so that the line segment extends monotonically in the −y direction, determines presence or absence of intersection between line segments with an opposite side including a y coordinate of the reference line in a line segment as an intersection determination target, and excludes remaining line segments from intersection determination targets with respect to the reference line.

16. An apparatus for determining line segment intersections in a figure of writing data, comprising:
a storage device configured to store writing data;
a shape determination circuit configured to read the writing data from the storage device and determine a shape of a figure for each of figures with one of two directions perpendicular to each other as an x direction and the other as a y direction; and
an intersection determination processing circuit configured to perform different intersection determination processing according to the shape of the figure,
wherein in a case that the shape of the figure is a polygon as neither an x-monotone polygon nor a y-monotone polygon as a result of the shape determination, the intersection determination processing circuit calculates a displacement direction of an x coordinate and a displacement direction of a y coordinate of a next vertex from a position of a previous vertex for each of a plurality of vertices forming the polygon, and determines presence or absence of intersection between line segments by using one of the x direction and the y direction as a scanning direction, the number of vertices with displacement directions changing from a positive direction to a negative direction or from the negative direction to the positive direction in the one direction being smaller than that in the other direction.

17. A non-transitory computer-readable storage medium storing a program for causing a computer to execute processing comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein in a case that the shape of the figure is an xy-monotone polygon and a convex polygon as a result of the shape determination, the intersection determination processing is omitted.

18. A non-transitory computer-readable storage medium storing a program for causing a computer to execute processing comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is an x-monotone polygon as a result of the shape determination, a line segment having an end point with a position increasing in the x direction so that the line segment extends monotonically in the x direction or having an end point with a position decreasing in the x direction so that the line segment extends monotonically in the −x direction is set as a reference line, presence or absence of intersection between line segments is determined with an opposite side including an x coordinate of the reference line in a line segment as an intersection determination target, and remaining line segments are excluded from intersection determination targets with respect to the reference line.

19. A non-transitory computer-readable storage medium storing a program for causing a computer to execute processing comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a y-monotone polygon as a result of the shape determination, a line segment having an end point with a position increasing in the y direction so that the line segment extends monotonically in the y direction or having an end point with a position decreasing in the y direction so that the line segment extends monotonically in the −y direction is set as a reference line, presence or absence of intersection between line segments is determined with an opposite side including a y coordinate of the reference line in a line segment as an intersection determination target, and remaining line segments are excluded from intersection determination targets with respect to the reference line.

20. A non-transitory computer-readable storage medium storing a program for causing a computer to execute processing comprising:
storing writing data in a storage device;
reading the writing data from the storage device and determining a shape of a figure for each of figures with one of two directions perpendicular to each other as an x direction and the other as a y direction; and
performing different intersection determination processing according to the shape of the figure and outputting a result,
wherein, in the intersection determination processing, in a case that the shape of the figure is a polygon as neither an x-monotone polygon nor a y-monotone polygon as a result of the shape determination, a displacement direction of an x coordinate and a displacement direction of a y coordinate of a next vertex from a position of a previous vertex are calculated for each of a plurality of vertices forming the polygon, and presence or absence of intersection between line segments is determined by using one of the x direction and the y direction as a scanning direction, the number of vertices with displacement directions changing from a positive direction to a negative direction or from the negative direction to the positive direction in the one direction being smaller than that in the other direction.

21. An electron beam lithography apparatus, comprising:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is an xy-monotone polygon and a convex polygon as a result of the shape determination, the intersection determination processing is omitted.

22. An electron beam lithography apparatus, comprising:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is an x-monotone polygon as a result of the shape determination, the intersection determination processing circuit sets, as a reference line, a line segment having an end point with a position increasing in the x direction so that the line segment extends monotonically in the x direction or having an end point with a position decreasing in the x direction so that the line segment extends monotonically in the −x direction, determines presence or absence of intersection between line segments with an opposite side including an x coordinate of the reference line in a line segment as an intersection determination target, and excludes remaining line segments from intersection determination targets with respect to the reference line.

23. An electron beam lithography apparatus, comprising:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is a y-monotone polygon as a result of the shape determination, the intersection determination processing circuit sets, as a reference line, a line segment having an end point with a position increasing in the y direction so that the line segment extends monotonically in the y direction or having an end point with a position decreasing in the y direction so that the line segment extends monotonically in the −y direction, determines presence or absence of intersection between line segments with an opposite side including a y coordinate of the reference line in a line segment as an intersection determination target, and excludes remaining line segments from intersection determination targets with respect to the reference line.

24. An electron beam lithography apparatus, comprising:
a storage device configured to store writing data;
a shape determination circuit configured to read the writing data from the storage device and determine a shape of a figure for each of figures with one of two directions perpendicular to each other as an x direction and the other as a y direction;
an intersection determination processing circuit configured to perform different intersection determination processing according to the shape of the figure; and
a writing mechanism configured to write a pattern of each figure where line segments do not intersect with each other on a target object by using an electron beam,
wherein in a case that the shape of the figure is a polygon as neither an x-monotone polygon nor a y-monotone polygon as a result of the shape determination, the intersection determination processing circuit calculates a displacement direction of an x coordinate and a displacement direction of a y coordinate of a next vertex from a position of a previous vertex for each of a plurality of vertices forming the polygon, and determines presence or absence of intersection between line segments by using one of the x direction and the y direction as a scanning direction, the number of vertices with displacement directions changing from a positive direction to a negative direction or from the negative direction to the positive direction in the one direction being smaller than that in the other direction.
